(19) United States
(12) Patent Application Publication
(10) Pub. No.: US 2026/0114162 A1
(43) Pub. Date: Apr. 23, 2026

(54) DISPLAY DEVICE

(71) Applicant: LG Display Co., Ltd., Seoul (KR)

(72) Inventors: Wonjong CHO, Paju-si (KR); TaeWoon KO, Seoul (KR)

(73) Assignee: LG Display Co., Ltd., Seoul (KR)

(21) Appl. No.: 19/094,805

(22) Filed: Mar. 28, 2025

(30) Foreign Application Priority Data
Oct. 18, 2024 (KR) 10-2024-0143152

(51) Int. Cl. H10K 59/80; H10K 59/124

(52) U.S. Cl. CPC H10K 59/879; H10K 59/124

(57) ABSTRACT

A display device according to an exemplary embodiment of the present disclosure includes a substrate including a plurality of sub pixels, a transistor disposed above the substrate, a planarization film which is disposed above the transistor and has a protrusion portion, an anode which is disposed on a top surface of the protrusion portion of the planarization film to form a main emission area of the sub pixel, an organic layer disposed on the anode, a cathode disposed on the organic layer, and a viewing angle enhancement film disposed under the substrate, in which two patterns with different refractive indexes are alternately disposed, to improve a luminance and a luminance viewing angle.

### CROSS-REFERENCE TO RELATED APPLICATIONS

This application claims the priority of Korean Patent Application No. 10-2024-0143152 filed on Oct. 18, 2024, in the Korean Intellectual Property Office, the disclosure of which is incorporated herein by reference.

### BACKGROUND

### Technical Field

The present disclosure relates to a display device.

### Discussion of the Related Art

As it enters the information era, a field of a display device which visually expresses electrical information signals has been rapidly developed and studies are continued to improve performances of various display devices, such as a thin-thickness, a light weight, and low power consumption.

A representative display device may include a liquid crystal display device (LCD), a field emission display device (FED), an electro-wetting display device (EWD), and an organic light emitting display device (OLED).

An electroluminescent display device which is represented by an organic light emitting display device is a self-emitting display device so that a separate light source is not necessary, which is different from a liquid crystal display device. Therefore, the electroluminescent display device may be manufactured to have a light weight and a small thickness. Further, since the electroluminescent display device is advantageous not only in terms of power consumption due to the low voltage driving, but also in terms of color implementation, a response speed, a viewing angle, and a contrast ratio (CR), it is expected to be utilized in various fields.
The electroluminescent display device configures a light emitting diode by disposing a plurality of organic layers each including an emission layer between two electrodes of an anode electrode and a cathode electrode. For example, when holes are injected from the anode electrode into the emission layer and electrons are injected from the cathode electrode into the emission layer, the injected holes and electrons are recombined in the emission layer to form excitons and emit light.

However, when the electroluminescent display device has a problem in that when there is light which does not go out from a display panel to be trapped in the display panel, among light emitted from an emission layer, a light extraction efficiency may be degraded to degrade a luminous efficiency.

An amount of light emitted from the emission layer is increased in accordance with a magnitude of current which is applied to the electroluminescent display device so that more current is applied to the emission layer to increase the luminance of the electroluminescent display device. However, power consumption is increased and the lifespan of the electroluminescent display device is also shortened.

### SUMMARY

Accordingly, embodiments of the present disclosure are directed to a display device that substantially obviates one or more of the problems due to limitations and disadvantages of the related art.

An aspect of the present disclosure is to provide a display device which improves luminous efficiency by improving a light extraction efficiency.

Another aspect of the present disclosure is to provide a display device in which luminous efficiency is improved to increase the lifespan.

Still another aspect of the present disclosure is to provide a display device in which luminous efficiency, luminance, and a luminance viewing angle are simultaneously improved.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate including a plurality of sub pixels, a transistor disposed above the substrate, a planarization film which is disposed above the transistor and has a protrusion portion, an anode which is disposed on a top surface of the protrusion portion of the planarization film to form a main emission area of the sub pixel, an organic layer disposed on the anode, a cathode disposed on the organic layer, and a viewing angle enhancement film disposed under the substrate, in which two patterns with different refractive indexes are alternately disposed.

Other detailed matters of the exemplary embodiments are included in the detailed description and the drawings.

According to the present disclosure, a display device includes a side mirror structure of a cathode to improve a light extraction efficiency. In this case, the power consumption may be reduced in accordance with the improvement of the luminance and a usage of fossil fuel for power generation is reduced at a low power to reduce greenhouse gas emission, thereby implementing environment/social/governance (ESG).

According to the present disclosure, a display device which applies an improved four-stack element structure to improve the luminance may be provided.

According to the present disclosure, a display device in which a viewing angle enhancement film is disposed below the display panel to improve the luminance viewing angle may be provided. In this case, a defect, such as rainbow mura caused when it is applied to the existing lens may be suppressed and a yield may be improved.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a diagram exemplarily illustrating a display device according to the present disclosure;

FIG. 2 is a plan view schematically illustrating a display device according to the present disclosure;

FIG. 3 is a plan view illustrating a pixel structure of a display panel according to a first exemplary embodiment of the present disclosure;

FIG. 4 is a cross-sectional view taken along A-A′ of FIG. 3;

FIG. 5 is a cross-sectional view taken along B-B′ of FIG. 3;

FIG. 6 is a cross-sectional view exemplarily illustrating a structure of a light emitting diode of a sub pixel of a display panel of FIG. 3;

FIG. 7 is a graph of an electroluminescence (EL) spectrum according to a wavelength;

FIGS. 8A to 8E are views illustrating a manufacturing process of a viewing angle enhancement film of FIG. 7 as an example;

FIG. 9 is a view illustrating a part of a cross-section of a display device according to a second exemplary embodiment of the present disclosure;

FIG. 10 is a view illustrating a part of a cross-section of a display device according to a third exemplary embodiment of the present disclosure;

FIGS. 11A to 11F are views illustrating a manufacturing process of a viewing angle enhancement film of FIG. 10 as an example;

FIG. 12 is a view illustrating a part of a cross-section of a display device according to a fourth exemplary embodiment of the present disclosure; and

FIG. 13 is a view illustrating a part of a cross-section of a display device according to a fifth exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately”or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to the drawings.

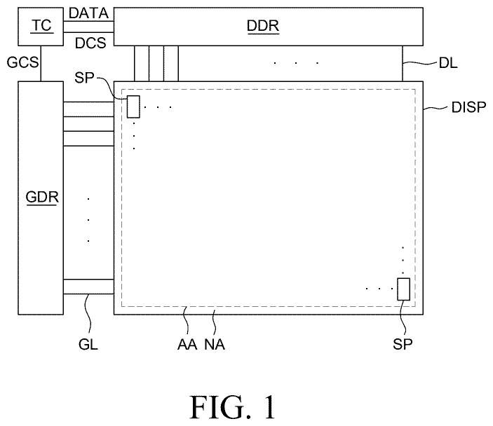

FIG. 1 is a diagram exemplarily illustrating a display device according to the present disclosure.

A display device according to exemplary embodiments of the present disclosure may include a display device, an illumination device, an electroluminescent display device, and the like. Hereinafter, for the convenience of description, the display device will be mainly described. However, the following description will be applied to other various display devices, such as an illumination device or an electroluminescent display device, in the same way.

Referring to FIG. 1, the display device according to the exemplary embodiments of the present disclosure may include a display panel DISP which displays an image or outputs light and a driving circuit which drives the display panel DISP.

In the display panel DISP, a plurality of data lines DL and a plurality of gate lines GL are disposed and a plurality of sub pixels SP defined by the plurality of data lines DL and the plurality of gate lines GL may be disposed in a matrix.

The plurality of data lines DL and the plurality of gate lines GL of the display panel DISP intersect each other to be disposed. For example, the plurality of gate lines GL may be disposed in the unit of rows or columns and the plurality of data lines DL may be disposed in the unit of columns or rows. Hereinafter, for the convenience of description, it is assumed that the plurality of gate lines GL is disposed in rows and the plurality of data lines DL is disposed in columns.

In the display panel DISP, according to a sub pixel structure, other types of signal lines may be disposed, other than the plurality of data lines DL and the plurality of gate lines GL. For example, a driving voltage line, a reference voltage line, a common voltage line, or the like may be further disposed.

The display panel DISP may be various types of panels, such as a liquid crystal display (LCD) panel or an organic light emitting diode (OLED) panel.

Types of signal lines disposed in the display panel DISP may vary depending on a sub pixel structure or a panel type. Further, in the present disclosure, a signal line may be a concept including an electrode to which a signal is applied.

The display panel DISP may include an active area AA in which images are displayed and a non-active area NA which is an outer periphery of the active area AA and does not display images. Here, the non-active area NA is also referred to as a bezel area.

In the active area AA, a plurality of sub pixels SP may be disposed to display images.

In the non-active area NA, a pad unit to which a data driver DDR is electrically connected is disposed and a plurality of data link lines may be disposed to connect the pad unit and the plurality of data lines DL. Here, the plurality of data link lines is parts formed by extending the plurality of data lines DL to the non-active area NA or separate patterns which are electrically connected to the plurality of data lines DL.

Further, in the non-active area NA, gate driving-related lines may be disposed to transmit a voltage required for gate-driving to the gate driver GDR through the pad unit to which the above-described data driver DDR is electrically connected. For example, the gate driving-related lines may include a clock line which transmits a clock signal, a gate voltage line which transmits a gate voltage, and a gate driving control signal line which transmits various control signals required to generate a scan signal. Such gate driving-related lines may be disposed in the non-active area NA, unlike the gate line GL which is disposed in the active area AA.

For example, the driving circuit may include a data driver DDR which drives the plurality of data lines DL, a gate driver GDR which drives the plurality of gate lines GL, and a timing controller TC which controls the data driver DDR and the gate driver GDR.

As described above, the data driver DDR outputs a data voltage to the plurality of data lines DL to drive the plurality of data lines DL.

Further, the gate driver GDR outputs the scan signal to the plurality of gate lines GL to drive the plurality of gate lines GL.

For example, the timing controller TC supplies various control signals DCS and GCS required for the driving operations of the data driver DDR and the gate driver GDR to control the driving operations of the data driver DDR and the gate driver GDR. Further, the timing controller TC may supply image data DATA to the data driver DDR.

The timing controller TC starts scanning according to a timing implemented in each frame, may convert input image data input from the outside to be suitable for a data signal form used by the data driver DDR to output the converted image data DATA, and may control data driving at a proper time in accordance with the scanning.

For example, the timing controller TC receives timing signals, such as a vertical synchronization signal, a horizontal synchronization signal, an input data enable signal, and a clock signal, from the outside to control the data driver DDR and the gate driver GDR to generate various control signals. Therefore, the timing controller may output the various generated control signals to the data driver DDR and the gate driver GDR.

For example, in order to control the gate driver GDR, the timing controller TC may output various gate control signals GCS including a gate start pulse GSP, a gate shift clock GSC, and a gate output enable signal GOE.

Further, in order to control the data driver DDR, the timing controller TC may output various data control signals DCS including a source start pulse SSP, a source sampling clock SSC, and a source output enable signal SOE.

The timing controller TC may be implemented as a component separated from the data driver DDR or may be integrated with the data driver DDR to be implemented as an integrated circuit.

The data driver DDR receives image data DATA from the timing controller TC to supply a data voltage to the plurality of data lines DL to drive the plurality of data lines DL. The data driver DDR is also referred to as a source driver.

The data driver DDR may exchange various signals with the timing controller TC through various interfaces.

Further, the gate driver GDR sequentially supplies the scan signal to the plurality of gate lines GL to sequentially drive the plurality of gate lines GL. Here, the gate driver GDR is also referred to as a scan driver.

The gate driver GDR may sequentially supply a scan signal of an on-voltage or an off-voltage to the plurality of gate lines GL in accordance with the control of the timing controller TC.

When a specific gate line is open by the gate driver GDR, the data driver DDR converts image data DATA received from the timing controller TC into an analog data voltage to supply the converted analog data voltage to the plurality of data lines DL.

The data driver DDR may be disposed on only one side of the display panel DISP or if necessary, may be disposed on both sides of the display panel DISP according to a driving method and a panel design method. For example, the data driver DDR may be disposed on or below the display panel DISP or disposed both on and below the display panel DISP.

The gate driver GDR may be disposed only one side of the display panel DISP or if necessary, may be disposed on both sides of the display panel DISP according to a driving method and a panel design method. For example, the gate driver GDR may be disposed in a left side or a right side of the display panel DISP or disposed in both the left side and the right side of the display panel DISP.

The data driver DDR may be implemented to include one or more source driver integrated circuits (SDIC).

For example, each source driver integrated circuit may include a shift register, a latch circuit, a digital to analog converter (DAC), or an output buffer. The data driver DDR may further include one or more analog to digital converters (ADC) if necessary.

Further, each source driver integrated circuit may be connected to a bonding pad of the display panel DISP as a tape automated bonding type (TAB) or a chip on glass (COG) type or may be disposed directly on the display panel DISP. If necessary, each source driver integrated circuit may be integrated in the display panel DISP to be disposed. Further, each source driver integrated circuit may be implemented as a chip on film (COF) type. In this case, each source driver integrated circuit is mounted on a circuit film to be electrically connected to the data line DL in the display panel DISP through the circuit film.

The gate driver GDR may be configured by a plurality of gate driving circuits. Here, the plurality of gate driving circuits may correspond to the plurality of gate lines GL, respectively.

For example, each gate driving circuit may include a shift register and a level shifter.

The gate driving circuit may be connected to the bonding pad of the display panel DISP as a tape automated bonding (TAB) type or a chip on glass (COG) type. Further, each gate driving circuit may be implemented as a chip on film (COF) type. In this case, each gate driving circuit is mounted on a circuit film to be electrically connected to the gate line GL in the display panel DISP through the circuit film. Further, each gate driving circuit is implemented as a gate in panel (GIP) type to be embedded in the display panel DISP. For example, each gate driving circuit may be directly formed on the display panel DISP.

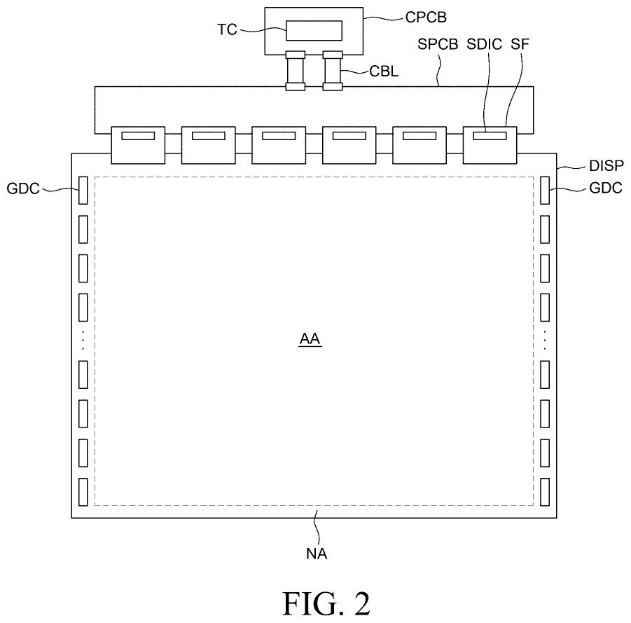

FIG. 2 is a plan view schematically illustrating a display device according to the present disclosure.

Referring to FIG. 2, in the display device according to exemplary embodiments of the present disclosure, the data driver is implemented as a chip on film (COF) type, among the above-described various types TAB, COG, and COF and the gate driver may be implemented as a gate in panel (GIP) type, among various types TAB, COG, COF, and GIP. However, it is not limited thereto and may be implemented as various types.

The data driver may be implemented by one or more source driver integrated circuits (SDIC). FIG. 2 illustrates that the data driver is implemented by a plurality of source driver integrated circuits (SDIC), but is not limited thereto.

When the data driver is implemented as a COF type, each source driver integrated circuit (SDIC) which implements a data driver may be mounted on the source-side circuit film SF.

For example, one side of the source-side circuit film SF may be electrically connected to a pad unit (an assembly of pads) disposed in the non-active area NA of the display panel DISP.

Further, wiring lines which electrically connect the source driver integrated circuit SDIC and the display panel DISP may be disposed on the source-side circuit film SF.

The display device may include one or more source printed circuit boards SPCB and a control printed circuit board CPCB for mounting control components and various electric devices, for circuit connections between the plurality of source driver integrated circuit SDIC and the other devices.

For example, the other side of the source-side circuit film SF in which the source driver integrated circuit SDIC is mounted may be connected to one or more source printed circuit boards SPCB. For example, one side of the source-side circuit film SF in which the source driver integrated circuit SDIC is mounted may be electrically connected to the non-active area NA of the display panel DISP and the other side may be electrically connected to the source printed circuit board SPCB.

Further, in the control printed circuit board CPCB, a timing controller TC which controls the operations of the data driver and the gate driver may be disposed.

In the control printed circuit board CPCB, a power management IC (PMIC) which supplies various voltages or currents to the display panel DISP, the data driver, and the gate driver or controls various voltages or currents to be supplied may be further disposed.

The source printed circuit board SPCB and the control printed circuit board CPCB may be circuitically connected through at least one connection member CBL.

For example, the connection member CBL may be a flexible printed circuit FPC, a flexible flat cable FFC, or the like.

For example, one or more source printed circuit boards SPCB and the control printed circuit board CPCB may be integrated as one printed circuit board.

When the gate driver is implemented as a gate in panel (GIP) type, the plurality of gate driving circuits GDC included in the gate driver may be directly formed on the non-active area NA of the display panel DISP.

Each gate driving circuit GDC may output the scan signal to a corresponding gate line disposed in the active area AA in the display panel DISP.

The plurality of gate driving circuits GDC disposed on the display panel DISP may be supplied with various signals (a clock signal, a high level gate voltage, a low level gate voltage, a start signal, and a reset signal) required to generate the scan signal through gate driving-related lines disposed in the non-active area NA.

The gate driving-related lines disposed in the non-active area NA may be electrically connected to the source-side circuit film SF which is the most adjacent to the plurality of gate driving circuits GDC.

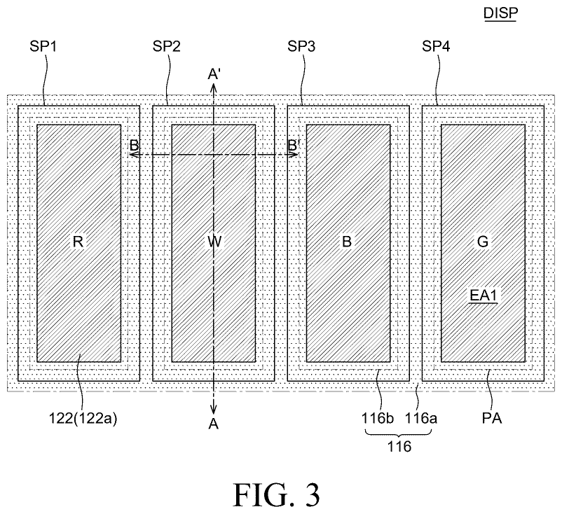

FIG. 3 is a plan view illustrating a pixel structure of a display panel according to a first exemplary embodiment of the present disclosure.

FIG. 3 illustrates a part of a display panel DISP in which four sub pixels SP1, SP2, SP3, and SP4 are disposed as an example and exemplarily illustrates an anode 122 which defines a main emission area EA1 and a second planarization film 116 including a protruding area PA.

Referring to FIG. 3, the display panel DISP according to the first exemplary embodiment of the present disclosure may include a pixel area in which a plurality of sub pixels SP1, SP2, SP3, and SP4 is provided and a wiring area in which various signal lines are disposed in the vicinity of the pixel area.

A plurality of first sub pixels SP1, second sub pixels SP2, third sub pixels SP3, and fourth sub pixels SP4 may be disposed in the pixel area.

For example, the first sub pixel SP1 may be a red sub pixel R, a second sub pixel SP2 may be a white sub pixel W, a third sub pixel SP3 may be a blue sub pixel B, and a fourth sub pixel SP4 may be a green sub pixel G. However, the present disclosure is not limited to the placement of the plurality of sub pixels SP1, SP2, SP3, and SP4.

For example, the first sub pixel SP1, the second sub pixel SP2, the third sub pixel SP3, and the fourth sub pixel SP4 may have a polygonal shape, such as a rectangle or a square, but are not limited thereto, and have various shapes, such as a circle or an oval. Here, a shape of the sub pixels SP1, SP2, SP3, and SP4 is defined by the shape of the anode 122 (specifically, a first area 122a of the anode 122), but it is not limited thereto.

In FIG. 3, it is illustrated that one first sub pixel SP1, one second sub pixel SP2, one third sub pixel SP3, and one fourth sub pixel SP4 are gathered to configure one pixel as an example, but are not limited thereto.

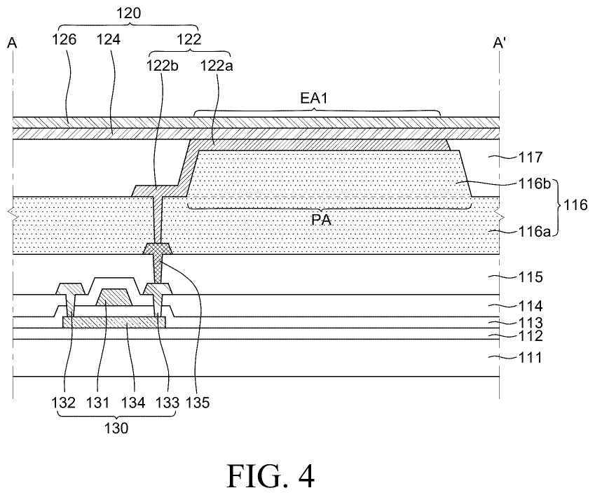

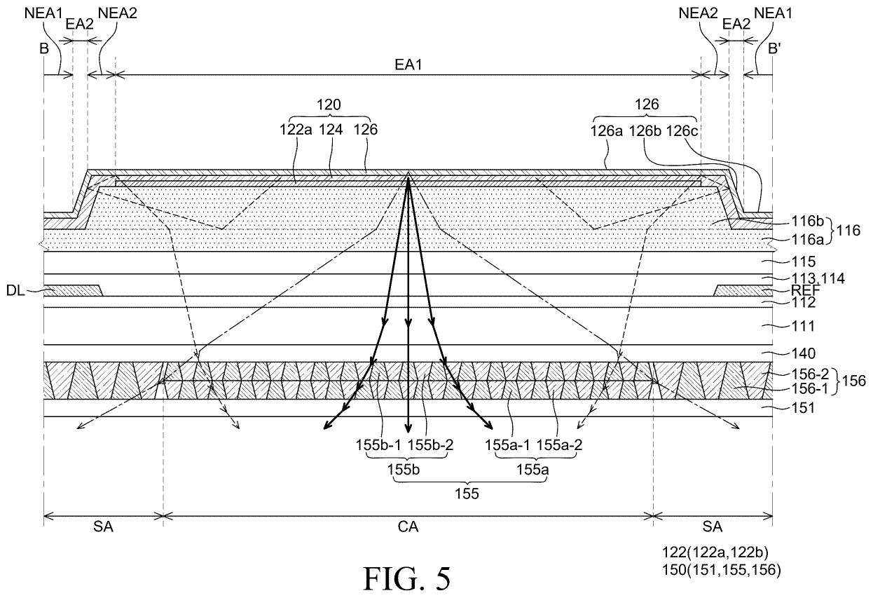

In the meantime, according to the present disclosure, due to the side mirror (SM) structure of the cathode, a reflective emission area is added as well as a main emission area EA1 so that each emission area may be expanded as compared with each of the sub pixels SP1, SP2, SP3, and SP4. The side mirror structure of the cathode will be described in detail with reference to FIGS. 4 and 5.

FIG. 4 is a cross-sectional view taken along A-A′ of FIG. 3.

FIG. 5 is a cross-sectional view taken along B-B′ of FIG. 3.

FIG. 4 illustrates a part of a cross-section of a white sub pixel of a display panel according to the first exemplary embodiment of the present disclosure which is vertically cut.

FIG. 5 illustrates a part of a cross-section of a white sub pixel of a display panel according to the first exemplary embodiment of the present disclosure which is horizontally cut.

Even though in FIGS. 4 and 5, configurations above the light emitting diode 120 are not illustrated for the convenience of description, the present disclosure may include an encapsulation structure above the light emitting diode 120.

Referring to FIGS. 4 and 5, a buffer layer 112, such as a multi-buffer layer or a lower buffer layer, may be disposed above the substrate 111.

Recently, the flexible substrate 111 may use a ductile material having a flexible characteristic, such as plastic.

The substrate 111 may be a film type including one of a group consisting of a polyester-based polymer, a silicon-based polymer, an acrylic polymer, a polyolefin-based polymer, and a copolymer thereof.

The substrate 111 may include a first substrate, a second substrate, and an insulating film. The insulating film may be disposed between the first substrate and the second substrate. As described above, the substrate 111 is configured by the first substrate, the second substrate, and the insulating film to suppress the moisture permeation. However, the present disclosure is not limited to the laminated structure of the substrate 111. For example, the first substrate and the second substrate may be polyimide (PI) substrates.

Various signal lines, such as a data line DL, a reference voltage line REF, or a common voltage line, may be disposed above the buffer layer 112. However, the present disclosure is not limited thereto and a data line DL, a reference voltage line REF, or a common voltage line may be disposed on the substrate 111. For example, the data line DL, the reference voltage line REF, or the common voltage line may be disposed in first and second non-emission areas NEA1 and NEA2 and a reflective emission area EA2 at the outside of the main emission area EA1.

For example, the multi-buffer layer may delay the spreading of the moisture or oxygen permeating the substrate 111 and may be formed by alternately laminating silicon nitride (SiNx) and silicon oxide (SiOx) at least once.

For example, the lower buffer layer may perform a function of protecting the semiconductor layer 134 and blocking various types of defects entering from the substrate 111.

For example, the lower buffer layer may be formed by amorphous silicon, silicon nitride (SiNx), or silicon oxide (SiOx).

A driving thin film transistor 130 may be disposed above the buffer layer 112.

Specifically, the semiconductor layer 134 may be disposed in the first non-emission area NEA1 above the substrate 111.

For example, the semiconductor layer 134 may be formed of a polycrystalline semiconductor and include a channel region, a source region, and a drain region. However, it is not limited thereto and the semiconductor layer 134 may be configured by amorphous silicon or oxide semiconductor.

The gate insulating film 113 may be disposed on the semiconductor layer 134.

The gate insulating film 113 may be configured by a single layer of silicon nitride (SiNx) or silicon oxide (SiOx) or a multilayer thereof, but is not limited thereto.

A gate line is disposed in a first direction and a gate electrode 131 which is connected to the gate line may be disposed, on the gate insulating film 113. However, the present disclosure is not limited thereto and the gate line may also be disposed on the buffer layer 112 together with the data line DL.

The gate electrode 131 may be disposed on the gate insulating film 113 so as to overlap the semiconductor layer 134.

For example, the gate electrode 131 and the gate line may be configured by a single layer or multiple layers of copper (Cu), aluminum (Al), molybdenum (Mo), chrome (Cr), gold (Au), titanium (Ti), nickel (Ni), and neodymium (Nd) which are conductive metals or an alloy thereof, but the present disclosure is not limited thereto.

An interlayer insulating film 114 may be disposed on the gate electrode 131 so as to cover the gate electrode 131.

For example, the interlayer insulating film 114 may be configured by a single layer of silicon nitride (SiNx) or silicon oxide (SiOx) or a multilayer thereof, but is not limited thereto.

At this time, a partial area of the interlayer insulating film 114 and the gate insulating film 113 is selectively removed to form a contact hole which exposes both ends of the semiconductor layer 134.

Further, a source electrode 132 and a drain electrode 133 which are connected to both ends of the semiconductor layer 134 may be each disposed on the interlayer insulating film 114.

The insulating film may be disposed above the source electrode 132 and the drain electrode 133. The insulating film may be a protection film, and may be omitted if necessary.

The protection film may be formed as a single layer of silicon nitride (SiNx) or silicon oxide (SiOx) or a multilayer thereof, but is not limited thereto.

Planarization films 115 and 116 may be disposed on the protection film.

The planarization films 115 and 116 may have a multilayered structure configured by at least two layers and for example, include a first planarization film 115 and a second planarization film 116. The first planarization film 115 is disposed to cover the driving thin film transistor 130 and expose a part of the source electrode 132 or the drain electrode 133 of the driving thin film transistor 130.

A thickness of the first planarization film 115 may be approximately 2 μm, but is not limited thereto.

The first planarization film 115 may be an overcoat layer.

For example, a connection electrode 135 may be disposed on the first planarization film 115 to electrically connect the driving thin film transistor 130 and the light emitting diode 120.

The connection electrode 135 may be configured with a material, such as copper (Cu), aluminum (Al), molybdenum (Mo), chrome (Cr), gold (Au), titanium (Ti), nickel (Ni), and neodymium (Nd), or an alloy thereof, but is not limited thereto.

A color filter CF may be disposed on the first planarization film 115.

The color filter CF converts a color of light emitted from the light emitting diode 120 and may be one of a red color filter, a green color filter, and a blue color filter.

At this time, for example, in a white sub pixel, a white color filter may be disposed or no color filter may be disposed.

The color filter CF may be formed of a material having a refractive index of approximately 1.5.

The second planarization film 116 may be disposed above the first planarization film 115 and the color filter CF.

In the display panel DISP according to the first exemplary embodiment of the present disclosure, the planarization films 115 and 116 are configured by two layers because as the resolution of the display panel DISP is increased, various signal lines are increased. Therefore, it is difficult to dispose all the wiring lines on one layer while ensuring a minimum interval so that an additional layer is provided. Such an additional layer, for example, the second planarization film 116 is added so that there is a margin for disposing wiring lines, which makes it easier to design and dispose the wiring lines/electrodes. Further, when a dielectric material is used for the planarization films 115 and 116 configured by a plurality of layers, the planarization films 115 and 116 may be utilized to form a capacitance between metal layers. However, the present disclosure is not limited thereto and the planarization films 115 and 116 may be configured as one layer.

The second planarization film 116 may be formed to expose a part of the connection electrode 135 and the drain electrode 133 of the driving thin film transistor 130 and the anode 122 of the light emitting diode 120 may be electrically connected by the connection electrode 135.

The planarization films 115 and 116 may be configured by one or more materials of acrylic resin, epoxy resin, phenolic resin, polyamides resin, polyimides resin, unsaturated polyesters resin, polyphenylene resin, benzocyclobutene, and polyphenylenesulfides resin, but are not limited thereto. For the convenience of description, the second planarization film 116 may be referred to as a planarization film.

According to the first exemplary embodiment of the present disclosure, the second planarization film 116 may include a bottom layer 116a disposed entirely in the main emission area EA1, the reflective emission area EA2, a first non-emission area NEA1, and a second non-emission area NEA2 on the first planarization film 115 and a protrusion portion 116b which is disposed on the bottom layer 116a and protrudes so as to correspond to the main emission area EA1, the reflective emission area EA2, and the second non-emission area NEA2 of each sub pixel.

As described above, in the first exemplary embodiment of the present disclosure, the second planarization film 116 has the protrusion portion 116b so that a top surface of the protrusion portion 116b of the second planarization film 116 and a top surface of the bank 117 may be flat. The top surface of the protrusion portion 116b may correspond to the first area 122a of the anode 122.

In the meantime, referring to FIG. 3, in the plan view, the main emission area EA1 or the protruding area PA may have approximately (or entirely) a polygonal shape, such as a rectangle. However, it is not limited thereto and may have various shapes, such as a circle or an oval.

For example, the protrusion portion 116b may include a top surface, a side portion, and a bottom surface.

The top surface of the protrusion portion 116b is a surface located at the top of the second planarization film 116 and may be substantially parallel to the substrate 111.

The top surface of the protrusion portion 116b on which the anode 122 is disposed may correspond to the main emission area EA1. Further, the top surface of the protrusion portion 116b may approximately (or entirely) have a polygonal shape, such as a rectangle, substantially the same as the main emission area EA1, in the plan view. However, as described above, the present disclosure is not limited thereto and may have various shapes, such as a circle or an oval.

A side portion of the protrusion portion 116b may be a surface extending from the top surface of the protrusion portion 116b to a side surface. For example, the side portion of the protrusion portion 116b may have a taper at a predetermined angle. In FIGS. 4 and 5, an example that the top surface and the side portion having straight line shapes of the protrusion portion 116b meet to form a vertex is illustrated, but the present disclosure is not limited thereto and the side portion of the protrusion portion 116b may have a gentle curved line.

Further, the bottom surface of the protrusion portion 116b is a surface which meets the bottom layer 116a and may be substantially parallel to the substrate 111. The bottom surface of the protrusion portion 116b may correspond to a protruding area PA. The bottom surface of the protrusion portion 116b may have approximately (or entirely) a polygonal shape, such as a rectangle, substantially the same as the protruding area PA, in the plan view. However, as described above, the present disclosure is not limited thereto and may have various shapes, such as a circle or an oval.

The bottom layer 116a and the protrusion portion 116b may be configured by materials having different refractive indexes, but are not limited thereto and may be integrally configured with the same material having the same refractive index. For example, the bottom layer 116a may be configured by a material having a lower refractive index and the protrusion portion 116b may be configured by a material having a higher refractive index.

For example, the protrusion portion 116b may have a height of approximately 1.0 μm to 1.5 μm, but is not limited thereto.

For example, the side portion of the protrusion portion 116b may have a taper at approximately 45 degrees to form a side mirror structure of the cathode 126, but is not limited thereto.

For example, the anode 122 may be disposed on a part of the top surface of the bottom layer 116a of the second planarization film 116 and a top surface and a side portion of the protrusion portion 116b. Further, for example, the anode 122 disposed in the main emission area EA1 may be in contact with the top surface of the protrusion portion 116b of the second planarization film 116.

The anode 122 may be disposed so as to correspond to each of the plurality of sub pixels. That is, the anode 122 may be disposed to be separated for each of the plurality of sub pixels. The anode 122 may be configured with a transparent conductive material, such as indium-tin-oxide (ITO) or indium-zinc-oxide (IZO) to allow light emitted from the light emitting diode 120 to the outside through a substrate 111 disposed on a rear surface. The anode 122 is a component for supplying holes to the organic layer 124 and may be configured with a material having a high work function. The anode 122 may have a single layer or multi-layered structure. In the case of a multi-layered structure, if materials with different refractive indexes are used, light distribution may be adjusted using the difference in refractive indexes. For example, in the multi-layered structure, a lower layer may have a refractive index larger than that of an upper layer.

The anode 122 may include a first area 122a which is disposed in a part of a top surface of the protrusion portion 116b of the second planarization film 116 and has a surface substantially parallel to a surface of the substrate 111.

Further, the anode 122 may include a second area 122b which extends from the first area 122a to a top surface of the bottom layer 116a of the second planarization film 116. For example, in the plan view, the second area 122b may be disposed in a lower edge of the main emission area EA1, but the present disclosure is not limited thereto.

For example, the second area 122b of the anode 122 may be spaced apart from the adjacent second area 122b with a predetermined distance to suppress the short-circuit between adjacent sub pixels.

In each sub pixel, the second planarization film 116 may include at least one contact hole which is spaced apart from the protruding area PA. The drain electrode 133 of the driving thin film transistor 130 and the second area 122b of the anode 122 may be electrically connected through the contact hole.

The bank 117 may be disposed on the bottom layer 116a of the second planarization film 116. For example, the bank 117 may be disposed on the bottom layer 116a above the driving thin film transistor 130.

The bank 117 may be formed of an organic material.

For example, the bank 117 may be formed of polyimide, acrylic, or benzocyclobutene resin, but is not limited thereto.

Further, the bank 117 may be formed of a black material. For example, the bank 117 may be configured such that the black pigment is dispersed in an organic material, but is not limited thereto and as long as the bank has a black color, the bank may be configured by an arbitrary black material.

At least a part of the bank 117 corresponding to the main emission area EA1 of the sub pixel may be open. That is, the bank 117 may be disposed at the outside of the main emission area EA1.

Further, the bank 117 of the first exemplary embodiment of the present disclosure may be disposed at left, right, upper and lower sides of the main emission area EA1 in different manners, but is not limited thereto. For example, at the left and right sides of the main emission area EA1, parts of the bank 117 corresponding to not only the main emission area EA1, but also the first and second non-emission areas NEA1 and NEA2 and the reflective emission area EA2 may be open. In contrast, at the upper and lower sides of the main emission area EA1, only a part of the bank 117 corresponding to the main emission area EA1 may be open. Accordingly, at the left and right sides of the main emission area EA1, the bank 117 may be in contact with the protrusion portion 116b or may be disposed to be adjacent to the protrusion portion 116b with the second area 122b interposed therebetween.

In the meantime, the main emission area EA1 may have a shape corresponding to a shape of the top surface of the protrusion portion 116b. When a shape of an arbitrary component corresponds to a shape of the other component, it means that the shape of the arbitrary component has the same shape as the other component, or has the same shape, but has a different size, or a shape of the arbitrary component is formed by transferring the shape of the other component by an arbitrary method. Accordingly, the shape of the main emission area EA1 is substantially understood to be formed by transferring a shape of the top surface of the protrusion portion 116b by light emitted from the organic layer 124 located on the top surface of the protrusion portion 116b.

Further, the reflective emission area EA2 does not overlap the main emission area EA1 and may be located while enclosing the main emission area EA1.

Further, the reflective emission area EA2 may be a closed curve which encloses the main emission area EA1. Alternatively, the reflective emission area EA2 may have a shape of the closed curve which partially has a break.

The sub pixels may be divided by the main emission area EA1.

The light emitting diode 120 which is electrically connected to the connection electrode 135 through a contact hole may be disposed above the second planarization film 116.

At this time, for example, the light emitting diode 120 may include an anode 122 connected to the drain electrode 133 of the driving thin film transistor 130, a plurality of organic layers 124 disposed on the anode 122, and a cathode 126 disposed on the organic layers 124. The organic layer 124 may be referred to as a light emitting unit, but is not limited to the term.

As described above, the anode 122 may be configured by a transparent conductive material.

Even though in FIGS. 4 and 5, for the convenience of description, an example that the anode 122 is configured as a single layer is illustrated, the present disclosure is not limited thereto and the anode may be configured by a multi-layered structure.

The organic layer 124 may be disposed above the anode 122.

For example, the organic layer 124 may include a hole injection layer, a hole transport layer, an emission layer, an electron transport layer, and an electron injection layer. In a tandem structure in which a plurality of emission layers is overlaid, a charge generation layer may be further disposed between the emission layers. For example, a common emission layer is formed in every sub pixel to emit white light regardless of the color and a color filter CF which distinguishes the colors may be separately provided. In this case, the emission layer may be individually disposed, but the hole injection layer, the electron injection layer, the hole transport layer, or the electron transport layer may be provided as a common layer to be disposed in each sub pixel in the same way.

In the meantime, at the left and right sides of the main emission area EA1, the organic layer 124 may be disposed on a top surface of the first area 122a of the anode 122, a part of a top surface and a side portion of the protrusion portion 116b, and a top surface of the bottom layer 116a. Further, at the upper and lower sides of the main emission area EA1, the organic layer 124 may be disposed on the top surface of the first area 122a of the anode 122 and the top surface of the bank 117, but is not limited thereto.

Further, the cathode 126 may be disposed on the organic layer 124 so as to be opposite to the anode 122 with the organic layer 124 therebetween.

The cathode 126 may be configured as a common layer without being separated for each of the plurality of sub pixels.

The cathode 126 may be formed of a metal material having a low work function to supply electrons to the organic layer 124. The cathode 126 may be configured with a metal material having a high reflectance to reflect light emitted from the organic layer 124 toward the substrate 111. For example, the cathode 126 may be configured by gold (Au), silver (Ag), aluminum (Al), molybdenum (Mo), and magnesium (Mg), or an alloy thereof, but is not limited thereto.

For example, the cathode 126 of the first exemplary embodiment of the present disclosure may include a first area 126a and a second area 126b. The first area 126a is disposed in the main emission area EA1 and the second non-emission area NEA2 and has a surface substantially parallel to a surface of the substrate 111. The second area 126b extends from the first area 126a and has a surface having a predetermined angle with respect to the substrate 111. The second area 126b of the cathode 126 may correspond to the side portion of the protrusion portion 116b. Therefore, the second area 126b of the cathode 126 may be referred to as a side portion of the cathode 126.

In the first exemplary embodiment of the present disclosure, the second area 126b of the cathode 126 is a part having a side-mirror shape and may configure the side mirror (SM) structure. The SM structure of the cathode 126 may be configured in the protruding area PA. For example, the SM structure of the cathode 126 may form a reflective emission area EA2. For example, the reflective emission area EA2 follows an outline of the main emission area EA1 and may have a frame shape without a break or a frame shape with a break. In the case of the frame shape with a break, the reflective emission area may enclose the outline of the main emission area EA1 and have breaks in the middle.

The second area 126b of the cathode 126 of the first exemplary embodiment of the present disclosure may be opposite to the side portion of the protrusion portion 116b along the shape of the side portion of the protrusion portion 116b. At this time, the second area 126b of the cathode 126 disposed in the side portion of the protrusion portion 116b may have a taper at an angle of approximately 30 degrees to 60 degrees, but is not limited thereto. The second area 126b of the cathode 126 configured with a metal material having a high reflectance may serve as a side mirror (SM). Accordingly, the emission area according to the first exemplary embodiment of the present disclosure may further include the reflective emission area EA2 by the SM structure, in addition to the main emission area EA1. For example, the reflective emission area EA2 may be formed between the first non-emission area NEA1 and the second non-emission area NEA2 of the anode 122. That is, the second non-emission area NEA2 may be formed between the reflective emission area EA2 and the main emission area EA1.

In the first exemplary embodiment of the present disclosure, the SM structure configured in the protruding area PA forms the reflective emission area EA2. A part of light emitted by the light emitting diode 120 is reflected from the second area 126b of the cathode 126 by the SM structure to form a frame-shaped reflective emission area EA2 (see a dotted-line arrow in FIG. 5). Therefore, the light extraction efficiency may be improved.

As described above, the light extraction efficiency is improved by the side mirror structure of the cathode 126, that is, the second area 126b. Specifically, trapped light of a substrate mode and a waveguide mode may be extracted by means of the second area 126b of the cathode 126. In this case, the power consumption may be reduced in accordance with the improvement of the luminance and a usage of fossil fuel for power generation is reduced at a low power to reduce greenhouse gas emission, thereby implementing environment/social/governance (ESG).

In the meantime, the data line DL, the reference voltage line REF, or the common voltage line may be disposed in first and second non-emission areas NEA1 and NEA2 and a reflective emission area EA2 at the outside of the main emission area EA1. That is, the data line DL, the reference voltage line REF, or the common voltage line may extend to the reflective emission area EA2 so that ends are located in the edge of the main emission area EA1. Further, there may be interruption in the light extraction path caused by the data line DL, the reference voltage line REF, or the common voltage line to further increase the light extraction efficiency.

An encapsulation layer may be disposed above the above-described light emitting diode 120.

Here, the encapsulation layer may have a single layer structure or a multi-layered structure. For example, the encapsulation layer may include a first encapsulation layer, a second encapsulation layer, and a third encapsulation layer.

For example, the first encapsulation layer and the third encapsulation layer may be configured by inorganic films and the second encapsulation layer may be configured by an organic film. For example, among the first encapsulation layer, the second encapsulation layer, and the third encapsulation layer, the second encapsulation layer is the thickest, so that the second encapsulation layer may serve as a planarization film.

The first encapsulation layer may be formed by the inorganic insulating material which can be subject to the low temperature deposition, and for example, may be configured by silicon nitride (SiNx), silicon oxide (SiOx), silicon oxynitride (SiON), or aluminum oxide (Al₂O₃).

The second encapsulation layer may be formed to have a smaller area than that of the first encapsulation layer. In this case, the second encapsulation layer may be formed to expose both ends of the first encapsulation layer.

Further, for example, the second encapsulation layer may be configured by an organic insulating material, such as acrylic resin, epoxy resin, polyimide, polyethylene, or silicon oxy carbon (SiOC). Further, for example, the second encapsulation layer may be formed by an inkjet method, but is not limited thereto.

The third encapsulation layer may be formed to cover a top surface and a side surface of each of the second encapsulation layer and the first encapsulation layer.

For example, the third encapsulation layer may minimize or block external moisture or oxygen permeating into the first encapsulation layer and the second encapsulation layer. Further, for example, the third encapsulation layer may be configured by an inorganic insulating material, such as silicon oxide (SiOx), silicon oxynitride (SiON), aluminum oxide (Al₂O₃), or silicon nitride (SiNx).

In the meantime, a polarization film 140, such as a circular polarizer or a polarizer may be disposed below the substrate 111.

Further, a viewing angle enhancement film 150 according to the first exemplary embodiment of the present disclosure may be disposed below the polarization film 140.

In order to increase front and viewing angle luminance, a lens may be disposed below the light emitting diode. However, in this case, issues, such as rainbow mura generated by the point light source or a black lifting phenomenon in the vicinity of the light source and yield reduction, may be caused.

Therefore, in the first exemplary embodiment of the present disclosure, the luminance is improved by applying an improved four-stack element structure and a luminance viewing angle is improved by placing the viewing angle enhancement film 150 below the display panel. That is, in the first exemplary embodiment of the present disclosure, the increased light extraction by the above-described four-stack element structure and the SM structure of the cathode 126 is dispersed in the center area CA and the side area SA through the viewing angle enhancement film 150. By doing this, the luminance viewing angle may be improved. Further, in the first exemplary embodiment of the present disclosure, a viewing angle improvement structure which is differentiated in the center area CA and the side area SA is applied.

The viewing angle enhancement film 150 of the first exemplary embodiment of the present disclosure may not be necessary to be disposed in the non-active area, other than the active area, but is not limited thereto.

The viewing angle enhancement film 150 of the first exemplary embodiment of the present disclosure may include a base member 151, a first pattern 155 disposed in the center area CA above the base member 151, and a second pattern 156 disposed in the side area SA.

For example, the first pattern 155 and the second pattern 156 may be disposed between the polarization film 140 and the base member 151, but are not limited thereto.

The center area CA is an area to which a front diffusion design is applied and may be located at the center of the main emission area EA1. The center area CA may improve the viewing angle by dividing the straight light. Therefore, the front straight light may be concentrated and diffused by the first pattern 155 (see solid-line arrow of FIG. 5).

The side area SA is an area to which a viewing angle diffusing design is applied and may be located at the outside of the center area CA. The side area SA may improve the viewing angle by adding diffused light. Further, the side area SA may be located in an edge of the main emission area EA1, the first and second non-emission areas NEA1 and NEA2, and the reflective emission area EA2. The viewing angle diffused light is further diffused by the second pattern 156 to improve the viewing angle (see two-dot chain line arrow of FIG. 5).

The base member 151 may be configured by cyclo olefin polymer (COP), but is not limited thereto and for example, may be configured by any one of triacetyl cellulose (TAC), polycarbonate (PC), and polyethylene terephthalate (PET).

Further, the first pattern 155 and the second pattern 156 may be configured by a reactive mesogen (RM). The RM may use a mesogen polymer, mesogen low-molecule, or oligomer having a photosensitive group having an optical anisotropy by linearly polarized light which is irradiated from the outside and a mesogen formation group having a mesophase in a specific temperature range or use a mixture thereof. However, the present disclosure is not limited thereto.

The viewing angle enhancement film 150 of the first exemplary embodiment of the present disclosure has a single-sided design in which the first pattern 155 and the second pattern 156 are provided on only one surface of the base member 151 so that double exposure may be applied to form one layer.

The first pattern 155 may be configured by two layers including an upper layer and a lower layer, but the second pattern 154 may be configured by a single layer, but the present disclosure is not limited thereto. In this case, the second pattern 156 may have a height and a size corresponding to the upper and lower layers of the first pattern 155.

The first pattern 155 may include a lower first pattern 155a located on a relatively lower layer and an upper first pattern 155b located on a relatively upper layer.

Further, the lower first pattern 155a may include a lower 1-1-th pattern 155a-1 and a lower 1-2-th pattern 155a-2 which are alternately disposed. The lower 1-1-th pattern 155a-1 and the lower 1-2-th pattern 155a-2 may have different refractive indexes. For example, the lower 1-1-th pattern 155a-1 may have a refractive index higher than that of the lower 1-2-th pattern 155a-2.

Desirably, the lower 1-1-th pattern 155a-1 and the lower 1-2-th pattern 155a-2 may have interlaced trapezoidal shapes, but are not limited thereto and the lower 1-1-th pattern 155a-1 and the lower 1-2-th pattern 155a-2 may have rectangular or square shapes. However, if one side is missing, like a triangle, light spreading cannot be used and a side surface needs to have an inclination of approximately 80 degrees to spread light well so that the trapezoidal shape is desirable.

Further, the upper first pattern 155b may include an upper 1-1-th pattern 155b-1 and an upper 1-2-th pattern 155b-2 which are alternately disposed. The upper 1-1-th pattern 155b-1 and the upper 1-2-th pattern 155b-2 may have different refractive indexes. For example, the upper 1-1-th pattern 155b-1 may have a refractive index higher than that of the upper 1-2-th pattern 155b-2.

Desirably, the upper 1-1-th pattern 155b-1 and the upper 1-2-th pattern 155b-2 may have interlaced trapezoidal shapes, but are not limited thereto and the upper 1-1-th pattern 155b-1 and the upper 1-2-th pattern 155b-2 may have rectangular or square shapes.

For example, the lower 1-1-th pattern 155a-1 and the upper 1-1-th pattern 155b-1 may have substantially the same refractive index and the lower 1-2-th pattern 155a-2 and the upper 1-2-th pattern 155b-2 may have substantially the same refractive index.

Further, the lower first pattern 155a and the upper first pattern 155b may be vertically interlaced to be disposed. For example, the upper 1-2-th pattern 155b-2 may be disposed on the lower 1-1-th pattern 155a-1 and the upper 1-1-th pattern 155b-1 may be disposed on the lower 1-2-th pattern 155a-2.

As described above, the lower first pattern 155a and the upper first pattern 155b having different refractive indexes may be disposed to be adjacent to each other horizontally and vertically. This is because when materials having different refractive indexes are disposed to be adjacent to each other in horizontal and vertical directions, light is bent multiple times which is effective in terms of luminance viewing angle.

The second pattern 156 may include a 2-1-th pattern 156-1 and a 2-2-th pattern 156-2 which are alternately disposed. The 2-1-th pattern 156-1 and the 2-2-th pattern 156-2 may have different refractive indexes.

For example, the 2-1-th pattern 156-1 may have a refractive index higher than that of the 2-2-th pattern 156-2.

Further, desirably, the 2-1-th pattern 156-1 and the 2-2-th pattern 156-2 may have interlaced trapezoidal shapes, but are not limited thereto and the 2-1-th pattern 156-1 and the 2-2-th pattern 156-2 may have rectangular or square shapes.

Further, for example, the lower 1-1-th pattern 155a-1, the upper 1-1-th pattern 155b-1, and the 2-1-th pattern 156-1 may have substantially the same refractive index and the lower 1-2-th pattern 155a-2, the upper 1-2-th pattern 155b-2, and the 2-2-th pattern 156-2 may have substantially the same refractive index. However, the present disclosure is not limited thereto. In this case, the lower 1-1-th pattern 155a-1, the upper 1-1-th pattern 155b-1, and the 2-1-th pattern 156-1 may have a refractive index higher than that of the lower 1-2-th pattern 155a-2, the upper 1-2-th pattern 155b-2, and the 2-2-th pattern 156-2.

Further, the 2-1-th pattern 156-1 may have substantially the same shape as the lower 1-1-th pattern 155a-1 and the upper 1-1-th pattern 155b-1 but have the larger size than the lower 1-1-th pattern 155a-1 and the upper 1-1-th pattern 155b-1.

Further, the 2-2-th pattern 156-2 may have substantially the same shape as the lower 1-2-th pattern 155a-2 and the upper 1-2-th pattern 155b-2 but have the larger size than the lower 1-2-th pattern 155a-2 and the upper 1-2-th pattern 155b-2.

Accordingly, light may be diffused from the side area SA more than from the center area CA.

Further, in the plan view, the lower 1-1-th pattern 155a-1, the lower 1-2-th pattern 155a-2, the upper 1-1-th pattern 155b-1, the upper 1-2-th pattern 155b-2, the 2-1-th pattern 156-1, and the 2-2-th pattern 156-2 may be disposed in parallel in one direction, but are not limited thereto.

Hereinafter, an example that the organic layer is configured by a plurality of stacks will be described in detail.

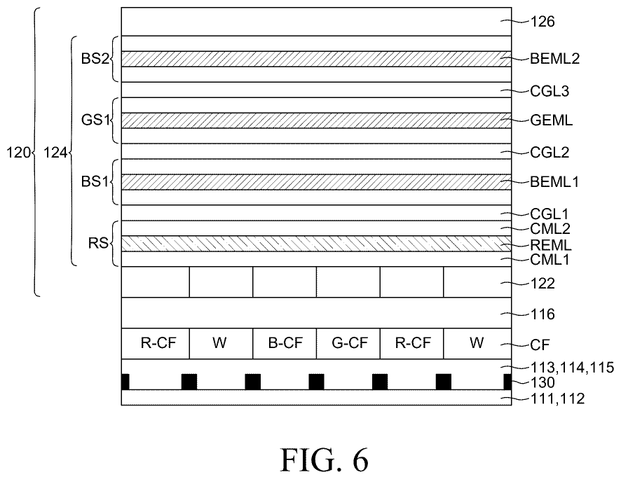

FIG. 6 is a cross-sectional view exemplarily illustrating a structure of a light emitting diode of a sub pixel of a display panel of FIG. 3.

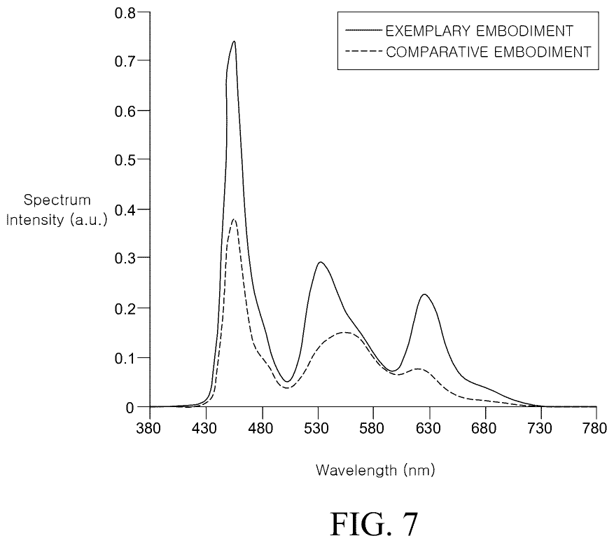

FIG. 7 is a graph of an electroluminescence spectrum according to a wavelength.

FIG. 6 exemplarily illustrates a structure of a light emitting diode 120 according to a first exemplary embodiment of the present disclosure equipped with four stacks RS, BS1, GS1, and BS2.

FIG. 7 illustrates an EL spectrum according to a wavelength of a comparative embodiment of a three-stack structure and an exemplary embodiment of a four-stack structure. The electroluminescence (EL) spectrum is configured by a sum of an emittance spectrum and a photoluminescence (PL) spectrum. The emittance spectrum refers to an amount of light emitted from a specific material or device in various wavelengths. The photoluminescence spectrum refers to a spectrum of light emitted from a material after absorbing the light (generally, UV or visible ray). The electroluminescence spectrum refers to a spectrum of light emitted from an electroluminescent display device when the electroluminescent display device receives a current.

For example, referring to FIG. 6, the organic layer 124 according to the first exemplary embodiment of the present disclosure may be configured by four stacks RS, BS1, GS1, and BS2. That is, FIG. 6 illustrates an example that the organic layer 124 is equipped with four stacks RS, BS1, GS1, and BS2, and a red phosphorescent stack RS, a first blue fluorescent stack BS1, a green phosphorescent stack GS, and a second blue fluorescent stack BS2 may be sequentially disposed from the anode 122. However, the present disclosure is not limited thereto.

The stacks RS, BS1, GS1, and BS2 may be separated by charge generation layers CGL1, CGL2, and CGL3. For example, a first charge generation layer CGL1 may be provided between the red phosphorescent stack RS and the first blue fluorescent stack BS1 and a second charge generation layer CGL2 may be provided between the first blue fluorescent stack BS1 and the green phosphorescent stack GS. Further, the third charge generation layer CGL3 may be provided between the green phosphorescent stack GS and the second blue fluorescent stack BS2.

The stack RS, BS1, GS, BS2 may include emission layers REML, BEML1, GEML, BEML2 with corresponding colors at the center, a hole transporting common layer CML1 below the emission layers REML, BEML1, GEML, BEML2, and an electron transporting common layer CML2 above the emission layers REML, BEML1, GEML, BEML2, respectively. At this time, the hole transporting common layer CML1 may include a hole injection layer, an electron blocking layer, and a hole transport layer and the electron transporting common layer CML2 may include a hole blocking layer, an electron transport layer, and the electron injection layer.

The red phosphorescent stack RS may include a red phosphorescent emission layer REML having an emission peak in a wavelength of 600 nm to 650 nm at the center and common layers therebelow and thereon. The green phosphorescent stack GS may include a green phosphorescent emission layer GEML having an emission peak in a wavelength of 510 nm to 590 nm at the center and common layers therebelow and thereon. The first and second blue fluorescent stacks BS1 and BS2 may include a first blue fluorescent emission layer BEML1 and a second blue fluorescent emission layer BEML2 and common layers therebelow and thereon, respectively. The first and second blue fluorescent emission layers BEML1 and BEML2 have an emission peak in a wavelength of 420 nm to 490 nm.

The first and second blue fluorescent emission layers BEML1 and BEML2 may have the same emission peak and may have slightly different emission peaks if necessary.

Referring to FIG. 7, it is understood that in an exemplary embodiment of a four-stack structure, as compared with the comparative embodiment of a three-stack structure, the intensity of the EL spectrum is increased in the red, green, and blue wavelength bands so that full white is improved.

As described above, in the display device of the present disclosure, a transmittance of the pure color of red, green, and blue may be improved by the four-stack structure of the light emitting diode 120.

In the display device of the present disclosure, different phosphorescent emission layers REML and GEML are provided in separate stacks RS and GS to improve color efficiency of each phosphorescent emission color and a color efficiency of green and red which occupy a larger portion of the white luminance may be supplemented.

Further, in the display device of the present disclosure, green and red phosphorescent stacks RS and GS are separately configured and in order to match the efficiency with a single phosphorescent stack, a plurality of blue fluorescent stacks BS1 and BS2 is provided. Therefore, a pure color efficiency may be increased and a color reproducibility may be improved.

Further, in the display device of the present disclosure, as compared with the three-stack structure in which phosphorescent emission layers are shared in one stack, when the same current is applied, the luminance value increases to have an effect of reducing the power consumption.

Further, the display device of the present disclosure does not apply an existing lens so that the defects, such as a rainbow mura or black lifting phenomenon due to the lens shape may be suppressed and the yield reduction may be improved.

In the meantime, as described above, the viewing angle enhancement film 150 of the first exemplary embodiment of the present disclosure has a single-sided design in which the first pattern 155 and the second pattern 156 are provided on only one surface of the base member 151 so that double exposure may be applied to form one layer. This will be described in detail with reference to the drawings.

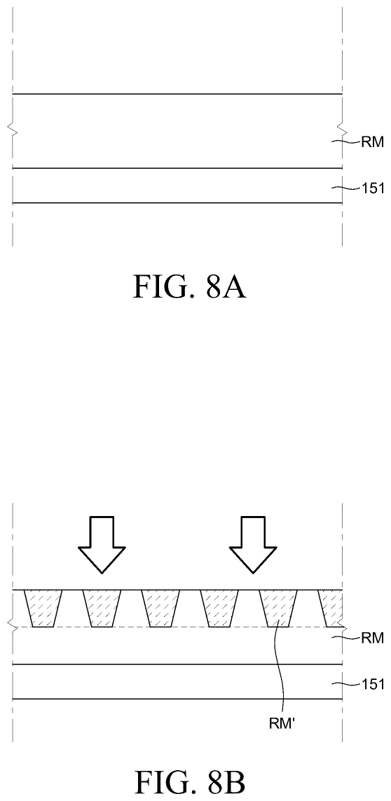

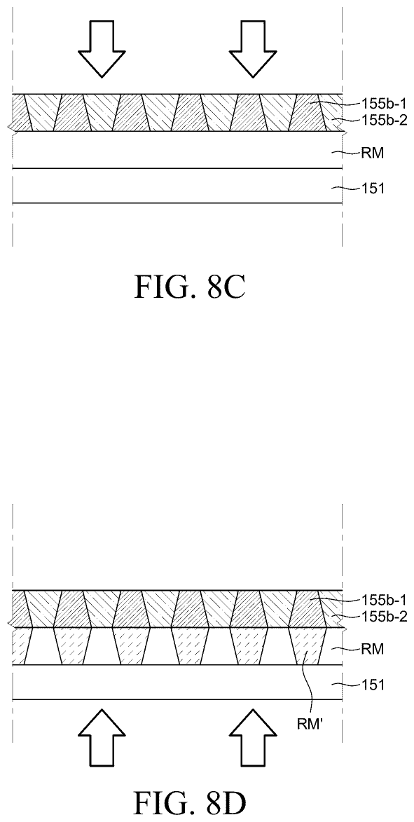

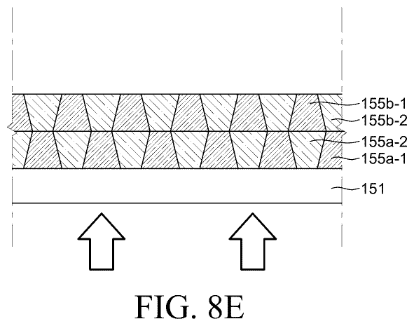

FIGS. 8A to 8E are views illustrating a manufacturing process of a viewing angle enhancement film of FIG. 7 as an example.

First, referring to FIG. 8A, an RM layer RM may be coated on the base member 151 by one process.

The base member 151 may be formed of a cycle olefin polymer (COP), but is not limited thereto and may be formed of one of triacetyl cellulose (TAC), polycarbonate (PC), polyethylene terephthalate (PET).

The RM layer RM may be formed of a reactive mesogen (RM).

Next, referring to FIG. 8B, an upper layer of the RM layer RM is cured by irradiating primary UV through a mask above the base member 151 to form a cured RM layer RM′. The cured RM layer RM′ may have the same shape as the upper 1-2-th pattern which will be formed later.

Next, referring to FIG. 8C, secondary UV may be irradiated above the base member 151.

At this time, the secondary UV irradiation may be performed by twisting at 90 degrees with respect to the primary UV irradiation. The secondary UV irradiation may be performed without a mask, but is not limited thereto.

The cured RM layer RM′ is cured twice due to the secondary UV irradiation to form the upper 1-2-th pattern 155b-2 and the other upper layer of the RM layer RM is cured once to form an upper 1-1-th pattern 155b-1.

Therefore, the upper 1-1-th pattern 155b-1 which is exposed (cured) once may have a refractive index larger than the upper 1-2-th pattern 155b-2 which is exposed (cured) twice.

At this time, the upper 1-1-th pattern 155b-1 and the upper 1-2-th pattern 155b-2 may be alternately disposed.

Desirably, the upper 1-1-th pattern 155b-1 and the upper 1-2-th pattern 155b-2 may have interlaced trapezoidal shapes, but are not limited thereto and the upper 1-1-th pattern 155b-1 and the upper 1-2-th pattern 155b-2 may have rectangular or square shapes.

Next, referring to FIG. 8D, a lower layer of the RM layer RM is cured by irradiating primary UV through a mask below the base member 151 to form a cured RM layer RM′. The cured RM layer RM′ may have the same shape as the lower 1-2-th pattern which will be formed later.

The cured RM layer RM′ may be located below the upper 1-1-th pattern 155b-1.

Next, referring to FIG. 8E, secondary UV may be irradiated below the base member 151.

At this time, the secondary UV irradiation may be performed by twisting at 90 degrees with respect to the primary UV irradiation. The secondary UV irradiation may be performed without a mask, but is not limited thereto.

The cured RM layer RM′ is cured twice due to the secondary UV irradiation to form the lower 1-2-th pattern 155a-2 and the other lower layer of the RM layer RM is cured once to form a lower 1-1-th pattern 155a-1.

Therefore, the lower 1-1-th pattern 155a-1 which is exposed (cured) once may have a refractive index larger than the lower 1-2-th pattern 155a-2 which is exposed (cured) twice.

At this time, the lower 1-1-th pattern 155a-1 and the lower 1-2-th pattern 155a-2 may be alternately disposed.

Desirably, the lower 1-1-th pattern 155a-1 and the lower 1-2-th pattern 155a-2 may have interlaced trapezoidal shapes, but are not limited thereto and the lower 1-1-th pattern 155a-1 and the lower 1-2-th pattern 155a-2 may have rectangular or square shapes.

For example, the upper 1-2-th pattern 155b-2 may be disposed on the lower 1-1-th pattern 155a-1 and the upper 1-1-th pattern 155b-1 may be disposed on the lower 1-2-th pattern 155a-2.

As described above, according to the first exemplary embodiment of the present disclosure, the center area divides straight light with a relatively small pattern to improve the viewing angle and the side area adds diffused light with a relatively large pattern to improve the viewing angle.

Further, according to the first exemplary embodiment of the present disclosure, one coating and double exposure may be applied with a single-sided design in which the first pattern and the second pattern are provided on only one surface of the base member.

In the meantime, according to the present disclosure, the second pattern may be formed to have a size corresponding to a size of the first pattern, which will be described in detail with respect to a second exemplary embodiment of the present disclosure.

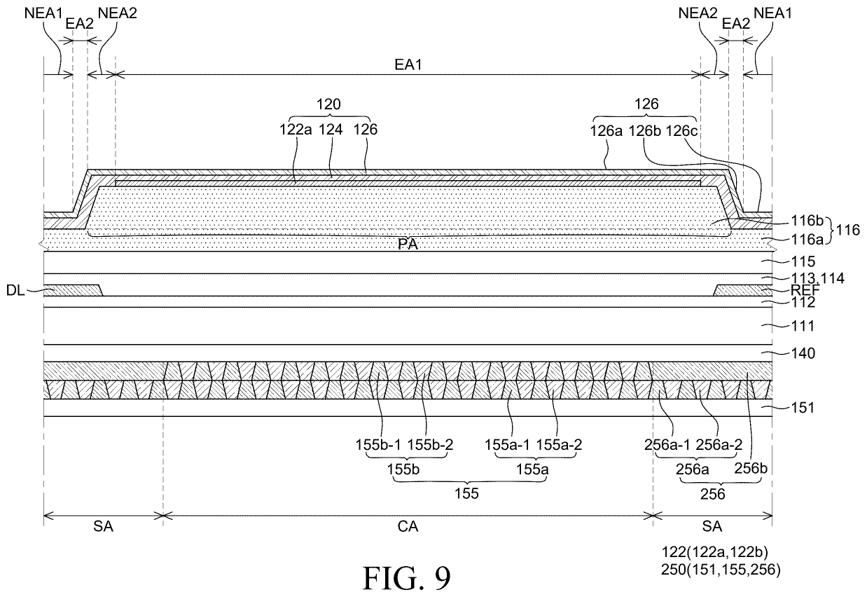

FIG. 9 is a view illustrating a part of a cross-section of a display device according to a second exemplary embodiment of the present disclosure.

FIG. 9 illustrates a part of a cross-section of a white sub pixel of a display device according to the second exemplary embodiment of the present disclosure, which is horizontally cut, as an example.

Even though in FIG. 9, configurations above the light emitting diode 120 are not illustrated for the convenience of description, the present disclosure may include an encapsulation structure above the light emitting diode 120.

In the second exemplary embodiment of the present disclosure of FIG. 9, only a size and a shape of the second pattern 256 are different from those of the first exemplary embodiment of FIGS. 3 to 8A to 8E, but the other configuration is substantially the same so that a redundant description will be omitted. The same configuration will be denoted with the same reference numeral. Here, the description for the same reference numeral may refer to FIGS. 1 to 8A to 8E.

Referring to FIG. 9, a buffer layer 112, such as a multi-buffer layer or a lower buffer layer, may be disposed above the substrate 111.

Various signal lines, such as a data line DL, a reference voltage line REF, or a common voltage line, may be disposed above the buffer layer 112. However, the present disclosure is not limited thereto and a data line DL, a reference voltage line REF, or a common voltage line may be disposed on the substrate 111. For example, the data line DL, the reference voltage line REF, or the common voltage line may be disposed in first and second non-emission areas NEA1 and NEA2 and a reflective emission area EA2 at the outside of the main emission area EA1.

A driving thin film transistor may be disposed above the buffer layer 112.

Planarization films 115 and 116 may be disposed above the driving thin film transistor.

The planarization films 115 and 116 may include a first planarization film 115 and a second planarization film 116.

A color filter may be disposed on the first planarization film 115.

The second planarization film 116 may be disposed above the first planarization film 115 and the color filter.

According to the second exemplary embodiment of the present disclosure, the second planarization film 116 may include a bottom layer 116a disposed on the entire surface of the substrate 111 and a protrusion portion 116b which is disposed on the bottom layer 116a and protrudes so as to correspond to a main emission area EA1, a reflective emission area EA2, and a second non-emission area NEA2 of each sub pixel.

For example, the protrusion portion 116b may include a top surface, a side portion, and a bottom surface.

The top surface of the protrusion portion 116b is a surface located at the top of the second planarization film 116 and may be substantially parallel to the substrate 111.

The top surface of the protrusion portion 116b on which the anode 122 is disposed may correspond to the main emission area EA1.

A side portion of the protrusion portion 116b may be a surface extending from the top surface of the protrusion portion 116b to a side surface. For example, the side portion of the protrusion portion 116b may have a taper at a predetermined angle.

Further, the bottom surface of the protrusion portion 116b is a surface which meets the bottom layer 116a and may be substantially parallel to the substrate 111. The bottom surface of the protrusion portion 116b may correspond to a protruding area PA.

The bottom layer 116a and the protrusion portion 116b may be configured by materials having different refractive indexes, but are not limited thereto and may be integrally configured with the same material having the same refractive index. For example, the bottom layer 116a may be configured by a material having a lower refractive index and the protrusion portion 116b may be configured by a material having a relatively higher refractive index.

For example, the anode 122 may be disposed so as to correspond to each of the plurality of sub pixels.

The anode 122 may include a first area 122a which is disposed in a part of the top surface of the protrusion portion 116b of the second planarization film 116 and has a surface substantially parallel to a surface of the substrate 111.

Further, the anode 122 may include a second area 112b (in FIG. 4) which extends from the first area 122a to a top surface of the bottom layer 116a of the second planarization film 116.

A bank may be disposed on the bottom layer 116a of the second planarization film 116.

In the meantime, the main emission area EA1 may have a shape corresponding to a shape of the top surface of the protrusion portion 116b.

Further, the reflective emission area EA2 does not overlap the main emission area EA1 and may be located while enclosing the main emission area EA1.

Further, the reflective emission area EA2 may be a closed curve which encloses the main emission area EA1.

The sub pixels may be divided by the main emission area EA1.

A light emitting diode 120 which is electrically connected to a connection electrode through a contact hole may be disposed above the second planarization film 116.

At this time, for example, the light emitting diode 120 may include an anode 122, a plurality of organic layers 124 disposed on the anode 122, and a cathode 126 disposed on the organic layers 124.

The organic layer 124 may be disposed above the anode 122.

As described above, the organic layer 124 according to the second exemplary embodiment of the present disclosure may be configured by four stacks. That is, in the organic layer 124, a red phosphorescent stack, a first blue fluorescent stack, a green phosphorescent stack, and a second blue fluorescent stack may be sequentially disposed from the anode 122, but is not limited thereto.

As described above, in the display device of the present disclosure, a transmittance of the pure color of red, green, and blue may be improved by the four-stack structure of the light emitting diode 120.

Further, in the display device of the present disclosure, different phosphorescent emission layers are provided in separate stacks to improve a color efficiency of each phosphorescent emission color and a color efficiency of green and red which occupy a larger portion of the white luminance may be supplemented.

Further, in the display device of the present disclosure, green and red phosphorescent stacks are separately configured and in order to match the efficiency with a single phosphorescent stack, a plurality of blue fluorescent stacks is provided. Therefore, a pure color efficiency may be increased and a color reproducibility may be improved.

Further, in the display device of the present disclosure, as compared with a three-stack structure in which phosphorescent emission layers are shared in one stack, when the same current is applied, the luminance value increases to have an effect of reducing the power consumption.

Further, the display device of the present disclosure does not apply an existing lens so that the defects, such as a rainbow mura or black lifting phenomenon due to the lens shape may be suppressed and the yield reduction may be improved.

In the meantime, the cathode 126 may be disposed on the organic layer 124 so as to be opposite to the anode 122 with the organic layer 124 therebetween.

The cathode 126 may be configured as a common layer without being separated for each of the plurality of sub pixels.

For example, the cathode 126 of the second exemplary embodiment of the present disclosure may include a first area 126a and a second area 126b. The first area 126a is disposed in the main emission area EA1 and the second non-emission area NEA2 and has a surface substantially parallel to a surface of the substrate 111. The second area 126b extends from the first area 126a and has a surface having a predetermined angle with respect to the substrate 111. The second area 126b of the cathode 126 may correspond to the side portion of the protrusion portion 116b.

In the second exemplary embodiment of the present disclosure, the second area 126b of the cathode 126 is a part having a side-mirror shape and may configure the side mirror (SM) structure.

The second area 126 of the cathode 126 of the second exemplary embodiment of the present disclosure may be opposite to the side portion of the protrusion portion 116b along the shape of the side portion of the protrusion portion 116b. Accordingly, the emission area according to the second exemplary embodiment of the present disclosure may further include the reflective emission area EA2 by the SM structure, in addition to the main emission area EA1.

As described above, the light extraction efficiency is improved by the side mirror structure of the cathode 126, that is, the second area 126b.

An encapsulation layer may be disposed above the above-described light emitting diode 120.

Further, a polarization film 140, such as a circular polarizer or a polarizer may be disposed below the substrate 111.

Further, a viewing angle enhancement film 250 according to the second exemplary embodiment of the present disclosure may be disposed below the polarization film 140.

The viewing angle enhancement film 250 of the second exemplary embodiment of the present disclosure is not necessary to be disposed in the non-active area, other than the active area, but is not limited thereto.

The viewing angle enhancement film 250 of the second exemplary embodiment of the present disclosure may include a base member 151, a first pattern 155 disposed in the center area CA above the base member 151, and a second pattern 256 disposed in the side area SA.

For example, the first pattern 155 and the second pattern 256 may be disposed between the polarization film 140 and the base member 151, but are not limited thereto.

The viewing angle enhancement film 250 of the second exemplary embodiment of the present disclosure has a single-sided design in which the first pattern 155 and the second pattern 256 are provided on only one surface of the base member 151, which is the same as the above-described first exemplary embodiment. Therefore, double exposure may be applied to form one layer.

Each of the first pattern 155 and the second pattern 256 may be configured by two layers including an upper layer and a lower layer, but the present disclosure is not limited thereto.

The first pattern 155 may include a lower first pattern 155a located on a relatively lower layer and an upper first pattern 155b located on a relatively upper layer.

Further, the lower first pattern 155a may include a lower 1-1-th pattern 155a-1 and a lower 1-2-th pattern 155a-2 which are alternately disposed. The lower 1-1-th pattern 155a-1 and the lower 1-2-th pattern 155a-2 may have different refractive indexes. For example, the lower 1-1-th pattern 155a-1 may have a refractive index higher than that of the lower 1-2-th pattern 155a-2.

Desirably, the lower 1-1-th pattern 155a-1 and the lower 1-2-th pattern 155a-2 may have interlaced trapezoidal shapes, but are not limited thereto and the lower 1-1-th pattern 155a-1 and the lower 1-2-th pattern 155a-2 may have rectangular or square shapes.

Further, the upper first pattern 155b may include an upper 1-1-th pattern 155b-1 and an upper 1-2-th pattern 155b-2 which are alternately disposed. The upper 1-1-th pattern 155b-1 and the upper 1-2-th pattern 155b-2 may have different refractive indexes. For example, the upper 1-1-th pattern 155b-1 may have a refractive index higher than that of the upper 1-2-th pattern 155b-2.

Desirably, the upper 1-1-th pattern 155b-1 and the upper 1-2-th pattern 155b-2 may have interlaced trapezoidal shapes, but are not limited thereto and the upper 1-1-th pattern 155b-1 and the upper 1-2-th pattern 155b-2 may have rectangular or square shapes.

For example, the lower 1-1-th pattern 155a-1 and the upper 1-1-th pattern 155b-1 may have substantially the same refractive index and the lower 1-2-th pattern 155a-2 and the upper 1-2-th pattern 155b-2 may have substantially the same refractive index.

Further, the lower first pattern 155a and the upper first pattern 155b may be vertically interlaced to be disposed. For example, the upper 1-2-th pattern 155b-2 may be disposed on the lower 1-1-th pattern 155a-1 and the upper 1-1-th pattern 155b-1 may be disposed on the lower 1-2-th pattern 155a-2.

The second pattern 256 may include a lower second pattern 256a located on a relatively lower layer and an upper second pattern 256b located on a relatively upper layer.

The lower second pattern 256a may include a lower 2-1-th pattern 256a-1 and a lower 2-2-th pattern 256a-2 which are alternately disposed. The lower 2-1-th pattern 256a-1 and the lower 2-2-th pattern 256a-2 may have different refractive indexes.

For example, the lower 2-1-th pattern 256a-1 may have a refractive index higher than that of the lower 2-2-th pattern 256a-2.

Further, desirably, the lower 2-1-th pattern 256a-1 and the lower 2-2-th pattern 256a-2 may have interlaced trapezoidal shapes, but are not limited thereto.

Further, the upper second pattern 256b may be configured by a single pattern.

The upper second pattern 256b may have substantially the same refractive index as the lower 2-1-th pattern 256a-1, but is not limited thereto.

Further, the lower 1-1-th pattern 155a-1, the upper 1-1-th pattern 155b-1, and the lower 2-1-th pattern 256a-1 and the upper second pattern 256b may have substantially the same refractive index. The lower 1-2-th pattern 155a-2, the upper 1-2-th pattern 155b-2, and the lower 2-2-th pattern 256a-2 may have substantially the same refractive index. However, the present disclosure is not limited thereto. The lower 1-1-th pattern 155a-1, the upper 1-1-th pattern 155b-1, the lower 2-1-th pattern 256a-1 and the upper second pattern 256b may have a refractive index higher than those of the lower 1-2-th pattern 155a-2, the upper 1-2-th pattern 155b-2, and the lower 2-2-th pattern 256a-2.

Further, the lower 1-1-th pattern 155a-1, the upper 1-1-th pattern 155b-1, and the lower 2-1-th pattern 256a-1 may have substantially the same shape and size. The lower 1-2-th pattern 155a-2, the upper 1-2-th pattern 155b-2, and the lower 2-2-th pattern 256a-2 may have substantially the same shape and size.

Further, as described above, the upper second pattern 256b may be configured by a single pattern.

Further, in the plan view, the lower 1-1-th pattern 155a-1, the lower 1-2-th pattern 155a-2, the upper 1-1-th pattern 155b-1, the upper 1-2-th pattern 155b-2, the lower 2-1-th pattern 256a-1, and the lower 2-2-th pattern 256a-2 may be disposed in parallel in one direction, but are not limited thereto.

In the meantime, as described above, the viewing angle enhancement film 250 of the second exemplary embodiment of the present disclosure has a single-sided design in which the first pattern 155 and the second pattern 256 are provided on only one surface of the base member 151 so that double exposure may be applied to form one layer.

The present disclosure may apply a double-sided design in which the first pattern and the second pattern are disposed on both surfaces of the base member, which will be described in detail with reference to a third exemplary embodiment of the present disclosure.

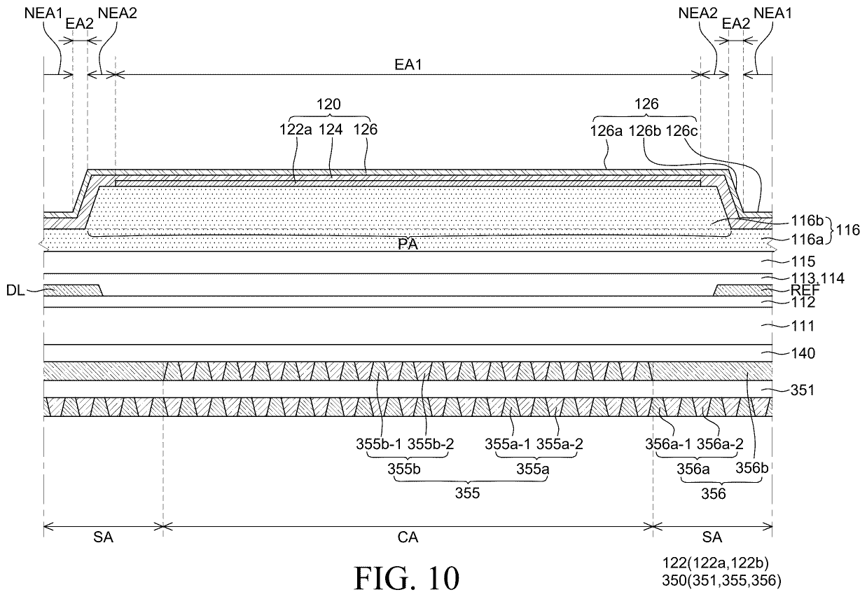

FIG. 10 is a view illustrating a part of a cross-section of a display device according to a third exemplary embodiment of the present disclosure.

FIG. 10 illustrates a part of a cross-section of a white sub pixel of a display device according to the second exemplary embodiment of the present disclosure, which is horizontally cut, as an example.

Even though in FIG. 10, configurations above the light emitting diode 120 are not illustrated for the convenience of description, the present disclosure may include an encapsulation structure above the light emitting diode 120.

In the third exemplary embodiment of the present disclosure of FIG. 10, only a viewing angle enhancement film 350 is different from those of the first exemplary embodiment of FIGS. 3 to 8A to 8E and the second exemplary embodiment of FIG. 9. However, the other configuration is substantially the same so that a redundant description will be omitted. Further, the same configuration will be denoted with the same reference numeral. Here, the description for the same reference numeral may refer to FIGS. 1 to 9.

Referring to FIG. 10, a viewing angle enhancement film 350 according to a third exemplary embodiment of the present disclosure may be disposed below the display panel.

The viewing angle enhancement film 350 of the third exemplary embodiment of the present disclosure is not necessary to be disposed in the non-active area, other than the active area, but is not limited thereto.

The viewing angle enhancement film 350 of the third exemplary embodiment of the present disclosure may include a base member 351, a first pattern 355 disposed in the center area CA above and below the base member 351, and a second pattern 356 disposed in the side area SA above and below the base member 351.

The viewing angle enhancement film 350 of the third exemplary embodiment of the present disclosure has a double-sided design in which the first pattern 355 and the second pattern 356 are provided on both surfaces of the base member 351, which is different from the above-described first and second exemplary embodiments. Therefore, double exposure may be applied to form one layer.

Each of the first pattern 355 and the second pattern 356 may be configured by an upper layer disposed above the base member 351 and a lower layer disposed below the base member 351, but the present disclosure is not limited thereto.

The first pattern 355 may include a lower first pattern 355a disposed below the base member 351 and an upper first pattern 355b disposed above the base member 351.

Further, the lower first pattern 355a may include a lower 1-1-th pattern 355a-1 and a lower 1-2-th pattern 355a-2 which are alternately disposed. The lower 1-1-th pattern 355a-1 and the lower 1-2-th pattern 355a-2 may have different refractive indexes. For example, the lower 1-1-th pattern 355a-1 may have a refractive index higher than that of the lower 1-2-th pattern 355a-2.

Desirably, the lower 1-1-th pattern 355a-1 and the lower 1-2-th pattern 355a-2 may have interlaced trapezoidal shapes, but are not limited thereto and the lower 1-1-th pattern 355a-1 and the lower 1-2-th pattern 355a-2 may have rectangular or square shapes.

Further, the upper first pattern 355b may include an upper 1-1-th pattern 355b-1 and an upper 1-2-th pattern 355b-2 which are alternately disposed. The upper 1-1-th pattern 355b-1 and the upper 1-2-th pattern 355b-2 may have different refractive indexes. For example, the upper 1-1-th pattern 355b-1 may have a refractive index higher than that of the upper 1-2-th pattern 355b-2.

Desirably, the upper 1-1-th pattern 355b-1 and the upper 1-2-th pattern 355b-2 may have interlaced trapezoidal shapes, but are not limited thereto and the upper 1-1-th pattern 355b-1 and the upper 1-2-th pattern 355b-2 may have rectangular or square shapes.

For example, the lower 1-1-th pattern 355a-1 and the upper 1-1-th pattern 355b-1 may have substantially the same refractive index and the lower 1-2-th pattern 355a-2 and the upper 1-2-th pattern 355b-2 may have substantially the same refractive index.

Further, the lower first pattern 355a and the upper first pattern 355b may be vertically interlaced to be disposed. For example, the upper 1-2-th pattern 355b-2 may be disposed above the lower 1-1-th pattern 355a-1 to be opposite to each other with the base member 351 therebetween and the upper 1-1-th pattern 355b-1 may be disposed above the lower 1-2-th pattern 355a-2 to be opposite to each other.

The second pattern 356 may include a lower second pattern 356a disposed below the base member 351 and an upper second pattern 356b disposed above the base member 351.

The lower second pattern 356a may include a lower 2-1-th pattern 356a-1 and a lower 2-2-th pattern 356a-2 which are alternately disposed. The lower 2-1-th pattern 356a-1 and the lower 2-2-th pattern 356a-2 may have different refractive indexes.

For example, the lower 2-1-th pattern 356a-1 may have a refractive index higher than that of the lower 2-2-th pattern 356a-2.

Further, desirably, the lower 2-1-th pattern 356a-1 and the lower 2-2-th pattern 356a-2 may have interlaced trapezoidal shapes, but are not limited thereto.

Further, the upper second pattern 356b may be configured by a single pattern.

The upper second pattern 356b may have substantially the same refractive index as the lower 2-1-th pattern 356a-1, but is not limited thereto.

Further, the lower 1-1-th pattern 355a-1, the upper 1-1-th pattern 355b-1, the lower 2-1-th pattern 356a-1 and the upper second pattern 356b may have substantially the same refractive index. The lower 1-2-th pattern 355a-2, the upper 1-2-th pattern 355b-2, and the lower 2-2-th pattern 356a-2 may have substantially the same refractive index. However, the present disclosure is not limited thereto. The lower 1-1-th pattern 355a-1, the upper 1-1-th pattern 355b-1, the lower 2-1-th pattern 356a-1 and the upper second pattern 356b may have a refractive index higher than those of the lower 1-2-th pattern 355a-2, the upper 1-2-th pattern 355b-2, and the lower 2-2-th pattern 356a-2.

Further, the lower 1-1-th pattern 355a-1, the upper 1-1-th pattern 355b-1, and the lower 2-1-th pattern 356a-1 may have substantially the same shape and size. The lower 1-2-th pattern 355a-2, the upper 1-2-th pattern 355b-2, and the lower 2-2-th pattern 356a-2 may have substantially the same shape and size.

Further, in the plan view, the lower 1-1-th pattern 355a-1, the lower 1-2-th pattern 355a-2, the upper 1-1-th pattern 355b-1, the upper 1-2-th pattern 355b-2, the lower 2-1-th pattern 356a-1, and the lower 2-2-th pattern 356a-2 may be disposed in parallel in one direction, but are not limited thereto.

According to the third exemplary embodiment of the present disclosure, the base member 351 is interposed between the lower 1-1-th pattern 355a-1, the lower 1-2-th pattern 355a-2, the lower 2-1-th pattern 356a-1, the lower 2-2-th pattern 356a-2 and the upper 1-1-th pattern 355b-1, the upper 1-2-th pattern 355b-2, the upper second pattern 356b. Therefore, as compared with the above-described second exemplary embodiment, the path of light is increased so that more light may be diffused.

In the meantime, as described above, the viewing angle enhancement film 350 of the third exemplary embodiment of the present disclosure has a double-sided design in which the first pattern 355 and the second pattern 356 are provided on both surfaces of the base member 351, which will be described in detail with reference to the drawing.

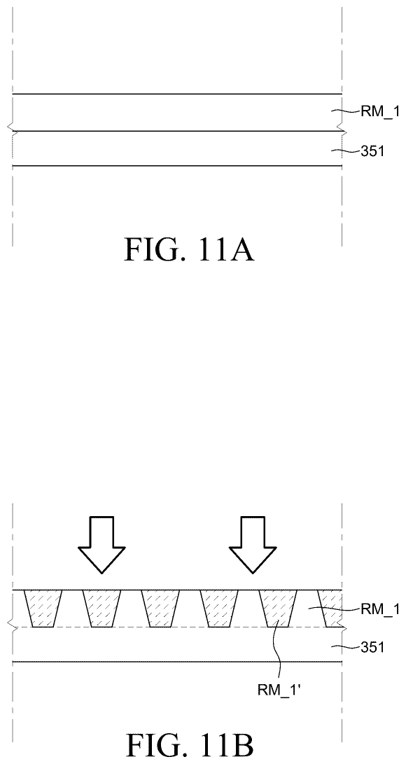

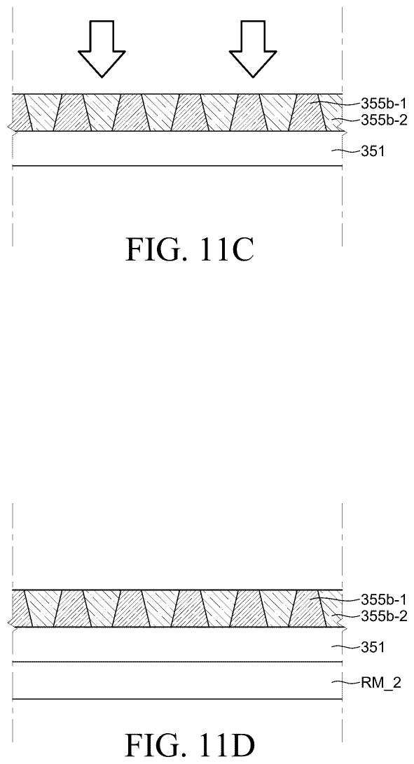

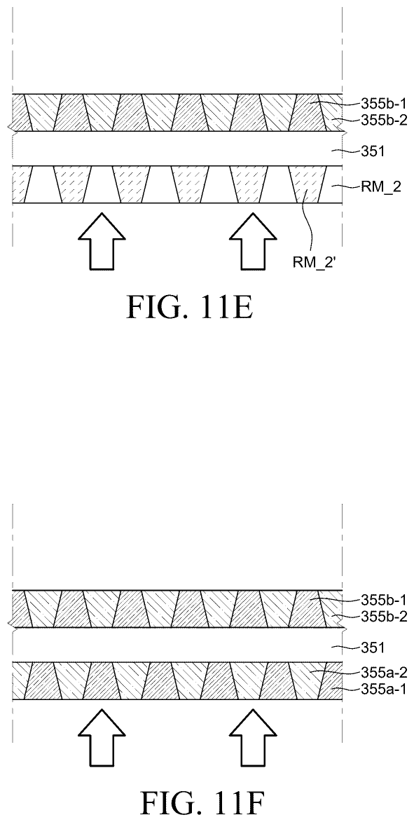

FIGS. 11A to 11F are views illustrating a manufacturing process of a viewing angle enhancement film of FIG. 10 as an example.

First, referring to FIG. 11A, a first RM layer RM_1 may be coated on the base member 351.

The first RM layer RM_1 may be formed of a reactive mesogen (RM).

Next, referring to FIG. 11B, a first RM layer RM_1 is cured by irradiating primary UV through a mask above the base member 351 to form a cured first RM layer RM_1′. The cured first RM layer RM_1′ may have the same shape as the upper 1-2-th pattern which will be formed later.

Next, referring to FIG. 11C, secondary UV may be irradiated above the base member 351.

At this time, the secondary UV irradiation may be performed by twisting at 90 degrees with respect to the primary UV irradiation. The secondary UV irradiation may be performed without a mask, but is not limited thereto.

The cured first RM layer RM_1′ is cured twice due to the secondary UV irradiation to form the upper 1-2-th pattern 355b-2 and the other part of the first RM layer RM_1 is cured once to form an upper 1-1-th pattern 355b-1.

Therefore, the upper 1-1-th pattern 355b-1 which is exposed (cured) once may have a refractive index larger than the upper 1-2-th pattern 355b-2 which is exposed (cured) twice.

At this time, the upper 1-1-th pattern 355b-1 and the upper 1-2-th pattern 355b-2 may be alternately disposed.

Desirably, the upper 1-1-th pattern 355b-1 and the upper 1-2-th pattern 355b-2 may have interlaced trapezoidal shapes, but are not limited thereto.

Next, referring to FIG. 11D, a second RM layer RM_2 may be coated below the base member 351.

The second RM layer RM_2 may be formed of a reactive mesogen (RM).

Next, referring to FIG. 11E, a second RM layer RM_2 is cured by irradiating primary UV through a mask below the base member 351 to form a cured second RM layer RM_2′. The cured second RM layer RM_2′ may have the same shape as the lower 1-2-th pattern which will be formed later.

The cured second RM layer RM_2′ may be located to be opposite to the upper 1-1-th pattern 355b-1.

Next, referring to FIG. 11F, secondary UV may be irradiated below the base member 351.

At this time, the secondary UV irradiation may be performed by twisting at 90 degrees with respect to the primary UV irradiation. The secondary UV irradiation may be performed without a mask, but is not limited thereto.

The cured second RM layer RM_2′ is cured twice due to the secondary UV irradiation to form the lower 1-2-th pattern 355a-2 and the other part of the second RM layer RM_2 is cured once to form a lower 1-1-th pattern 355a-1.

Therefore, the lower 1-1-th pattern 355a-1 which is exposed (cured) once may have a refractive index larger than the lower 1-2-th pattern 355a-2 which is exposed (cured) twice.

At this time, the lower 1-1-th pattern 355a-1 and the lower 1-2-th pattern 355a-2 may be alternately disposed.

Desirably, the lower 1-1-th pattern 355a-1 and the lower 1-2-th pattern 355a-2 may have interlaced trapezoidal shapes.

For example, the upper 1-2-th pattern 355b-2 may be disposed above the lower 1-1-th pattern 355a-1 with the base member 351 interposed therebetween to be opposite to each other and the upper 1-1-th pattern 355b-1 may be disposed above the lower 1-2-th pattern 355a-2 with the base member 351 interposed therebetween to be opposite to each other.

As described above, according to the third exemplary embodiment of the present disclosure, with the double-sided design in which the first pattern 355 and the second pattern 356 are formed on both surfaces of the base member 351, one more coating process is added compared with the above-described first and second exemplary embodiments. However, a boundary of upper and lower layers of the first pattern 355 and the second pattern 356 is clear, which is advantageous in terms of the process.

In the meantime, according to the present disclosure, the upper second pattern of the second pattern may be configured by a single pattern, which will be described in detail with respect to a fourth exemplary embodiment of the present disclosure.

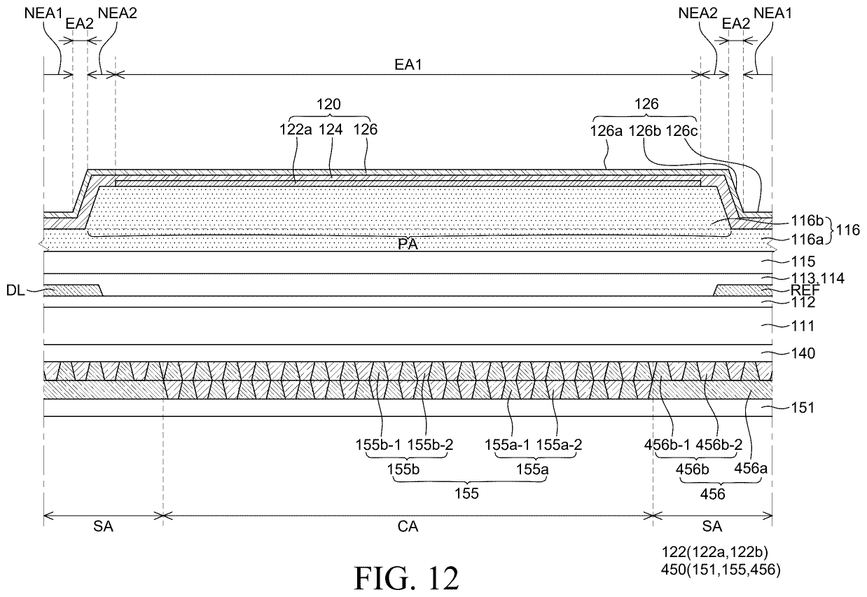

FIG. 12 is a view illustrating a part of a cross-section of a display device according to a fourth exemplary embodiment of the present disclosure.

FIG. 12 illustrates a part of a cross-section of a white sub pixel of a display device according to the fourth exemplary embodiment of the present disclosure, which is horizontally cut, as an example.

Even though in FIG. 12, configurations above the light emitting diode 120 are not illustrated for the convenience of description, the present disclosure may include an encapsulation structure above the light emitting diode 120.

In the fourth exemplary embodiment of the present disclosure of FIG. 12, only a second pattern 456 is different from that of the above-described second exemplary embodiment of FIG. 9, but the other configuration is substantially the same, so that a redundant description will be omitted. The same configuration will be denoted with the same reference numeral. Here, the description for the same reference numeral may refer to FIGS. 1 to 11A to 11F.

Referring to FIG. 12, a viewing angle enhancement film 450 according to a fourth exemplary embodiment of the present disclosure may be disposed below the display panel.

The viewing angle enhancement film 450 of the fourth exemplary embodiment of the present disclosure may include a base member 151, a first pattern 155 disposed in the center area CA above the base member 151, and a second pattern 456 disposed in the side area SA.

Each of the first pattern 155 and the second pattern 456 may be configured by two layers including an upper layer and a lower layer, but the present disclosure is not limited thereto.

The first pattern 155 is substantially the same as the above-described second exemplary embodiment, so that a description thereof will be omitted.

The second pattern 456 may include a lower second pattern 456a located on a relatively lower layer and an upper second pattern 456b located on a relatively upper layer.

The upper second pattern 456b may include an upper 2-1-th pattern 456b-1 and an upper 2-2-th pattern 456b-2 which are alternately disposed. The upper 2-1-th pattern 456b-1 and the upper 2-2-th pattern 456b-2 may have different refractive indexes.

For example, the upper 2-1-th pattern 456b-1 may have a refractive index higher than that of the upper 2-2-th pattern 456b-2.

Further, desirably, the upper 2-1-th pattern 456b-1 and the upper 2-2-th pattern 456b-2 may have interlaced trapezoidal shapes, but are not limited thereto.

Further, the lower second pattern 456a may be configured by a single pattern.

The lower second pattern 456a may have substantially the same refractive index as the upper 2-1-th pattern 456b-1, but is not limited thereto.

Further, the lower 1-1-th pattern 155a-1, the upper 1-1-th pattern 155b-1, and the upper 2-1-th pattern 456b-1 and the lower second pattern 456a may have substantially the same refractive index. The lower 1-2-th pattern 155a-2, the upper 1-2-th pattern 155b-2, and the upper 2-2-th pattern 456b-2 may have substantially the same refractive index. However, the present disclosure is not limited thereto. The lower 1-1-th pattern 155a-1, the upper 1-1-th pattern 155b-1, and the upper 2-1-th pattern 456b-1 and the lower second pattern 456a may have a refractive index higher than those of the lower 1-2-th pattern 155a-2, the upper 1-2-th pattern 155b-2, and the upper 2-2-th pattern 456b-2.

Further, the lower 1-1-th pattern 155a-1, the upper 1-1-th pattern 155b-1, and the upper 2-1-th pattern 456b-1 may have substantially the same shape and size. The lower 1-2-th pattern 155a-2, the upper 1-2-th pattern 155b-2, and the upper 2-2-th pattern 456b-2 may have substantially the same shape and size.

In the meantime, according to the present disclosure, a double-sided design may be applied and the upper second pattern of the second pattern may be configured by a single pattern, which will be described in detail with respect to a fifth exemplary embodiment of the present disclosure.

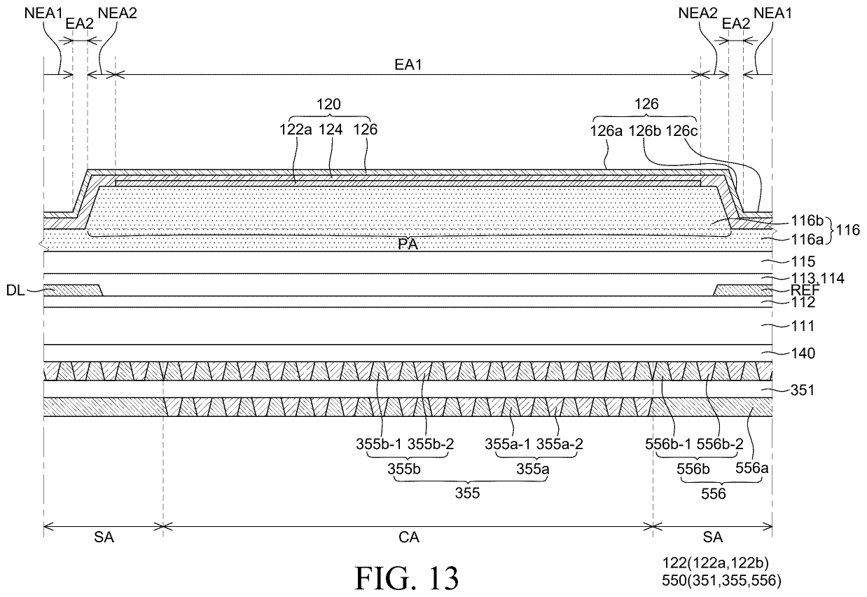

FIG. 13 is a view illustrating a part of a cross-section of a display device according to a fifth exemplary embodiment of the present disclosure.

FIG. 13 illustrates a part of a cross-section of a white sub pixel of a display device according to the fifth exemplary embodiment of the present disclosure, which is horizontally cut, as an example.

Even though in FIG. 13, configurations above the light emitting diode 120 are not illustrated for the convenience of description, the present disclosure may include an encapsulation structure above the light emitting diode 120.

In the fifth exemplary embodiment of the present disclosure of FIG. 13, only a second pattern 556 is different from that of the above-described third exemplary embodiment of FIG. 10, but the other configuration is substantially the same, so that a redundant description will be omitted. The same configuration will be denoted with the same reference numeral. Here, the description for the same reference numeral may refer to FIGS. 1 to 12.

Referring to FIG. 13, a viewing angle enhancement film 550 according to a fifth exemplary embodiment of the present disclosure may be disposed below the display panel.

The viewing angle enhancement film 550 of the fifth exemplary embodiment of the present disclosure may include a base member 351, a first pattern 355 disposed in the center area CA above and below the base member 351, and a second pattern 556 disposed in the side area SA above and below the base member 351.

The viewing angle enhancement film 550 of the fifth exemplary embodiment of the present disclosure has a double-sided design in which the first pattern 355 and the second pattern 556 are provided on both surfaces of the base member 351, which is the same as the above-described third exemplary embodiment.

Each of the first pattern 355 and the second pattern 556 may be configured by an upper layer disposed above the base member 351 and a lower layer disposed below the base member 351, but the present disclosure is not limited thereto.

The first pattern 355 is substantially the same as the above-described third exemplary embodiment, so that a description thereof will be omitted.

The second pattern 556 may include a lower second pattern 556a disposed below the base member 351 and an upper second pattern 556b disposed above the base member 351.

The upper second pattern 556b may include an upper 2-1-th pattern 556b-1 and an upper 2-2-th pattern 556b-2 which are alternately disposed. The upper 2-1-th pattern 556b-1 and the upper 2-2-th pattern 556b-2 may have different refractive indexes.

For example, the upper 2-1-th pattern 556b-1 may have a refractive index higher than that of the upper 2-2-th pattern 556b-2.

Further, desirably, the upper 2-1-th pattern 556b-1 and the upper 2-2-th pattern 556b-2 may have interlaced trapezoidal shapes, but are not limited thereto.

Further, the lower second pattern 556a may be configured by a single pattern.

The lower second pattern 556a may have substantially the same refractive index as the upper 2-1-th pattern 556b-1, but is not limited thereto.

Further, the lower 1-1-th pattern 355a-1, the upper 1-1-th pattern 355b-1, and the upper 2-1-th pattern 556b-1 and the lower second pattern 556a may have substantially the same refractive index. The lower 1-2-th pattern 355a-2, the upper 1-2-th pattern 355b-2, and the upper 2-2-th pattern 556b-2 may have substantially the same refractive index. However, the present disclosure is not limited thereto. The lower 1-1-th pattern 355a-1, the upper 1-1-th pattern 355b-1, and the upper 2-1-th pattern 556b-1 and the lower second pattern 556a may have a refractive index higher than those of the lower 1-2-th pattern 355a-2, the upper 1-2-th pattern 355b-2, and the upper 2-2-th pattern 556b-2.

Further, the lower 1-1-th pattern 355a-1, the upper 1-1-th pattern 355b-1, and the upper 2-1-th pattern 556b-1 may have substantially the same shape and size. The lower 1-2-th pattern 355a-2, the upper 1-2-th pattern 355b-2, and the upper 2-2-th pattern 556b-2 may have substantially the same shape and size.

The exemplary embodiments of the present disclosure can also be described as follows:

According to an aspect of the present disclosure, there is provided a display device. The display device includes a substrate including a plurality of sub pixels; a transistor disposed above the substrate, a planarization film which is disposed above the transistor and has a protrusion portion, an anode which is disposed on a top surface of the protrusion portion of the planarization film to form a main emission area of the sub pixel, an organic layer disposed on the anode; a cathode disposed on the organic layer and a viewing angle enhancement film disposed under the substrate, in which two patterns with different refractive indexes are alternately disposed.

The protrusion portion may further include a side portion which extends from the top surface of the protrusion portion to a side surface, and the cathode may include a first area disposed in the main emission area and a second non-emission area; and a second area which extends from the first area of the cathode to form a reflective emission area corresponding to the side portion of the protrusion portion.

The reflective emission area may be formed between the second non-emission area and a first non-emission area along an outline of the main emission area.

The viewing angle enhancement film may include a base member and a first pattern disposed in a center area above the base member and a second pattern disposed in a side area.

The center area may be located in a center of the main emission area and the side area may be disposed at an outside of the center area.

The first pattern may include a lower first pattern which is located on a relatively lower layer and an upper first pattern which is located on a relatively upper layer, the second pattern may be configured by a single layer, the lower first pattern may include a lower 1-1-th pattern and a lower 1-2-th pattern which are alternately disposed, the lower 1-1-th pattern and the lower 1-2-th pattern may have different refractive indexes, and the lower 1-1-th pattern and the lower 1-2-th pattern may have interlaced trapezoidal shapes.

The upper first pattern may include an upper 1-1-th pattern and an upper 1-2-th pattern which are alternately disposed, the upper 1-1-th pattern and the upper 1-2-th pattern may have different refractive indexes, and the upper 1-1-th pattern and the upper 1-2-th pattern may have interlaced trapezoidal shapes.

The upper 1-2-th pattern may be disposed on the lower 1-1-th pattern and the upper 1-1-th pattern may be disposed on the lower 1-2-th pattern.

The second pattern may include a 2-1-th pattern and a 2-2-th pattern which are alternately disposed, the 2-1-th pattern and the 2-2-th pattern may have different refractive indexes, and the 2-1-th pattern and the 2-2-th pattern may have interlaced trapezoidal shapes.

The 2-1-th pattern may have the same shape as the lower 1-1-th pattern and the upper 1-1-th pattern and may be larger than the lower 1-1-th pattern and the upper 1-1-th pattern, and the 2-2-th pattern nay have the same shape as the lower 1-2-th pattern and the upper 1-2-th pattern and may be larger than the lower 1-2-th pattern and the upper 1-2-th pattern.

The lower 1-1-th pattern, the upper 1-1-th pattern and the 2-1-th pattern may have the same refractive index and the lower 1-2-th pattern, the upper 1-2-th pattern and the 2-2-th pattern may have the same refractive index.

The first pattern may include a lower first pattern which is located on a relatively lower layer and an upper first pattern which is located on a relatively upper layer, and the second pattern may include a lower second pattern which is located on the relatively lower layer and an upper second pattern which is located on the relatively upper layer.

The lower first pattern may include a lower 1-1-th pattern and a lower 1-2-th pattern which are alternately disposed, the lower 1-1-th pattern and the lower 1-2-th pattern may have different refractive indexes, the lower second pattern may include a lower 2-1-th pattern and a lower 2-2-th pattern which are alternately disposed, the lower 2-1-th pattern and the lower 2-2-th pattern may have different refractive indexes, the lower 2-1-th pattern and the lower 2-2-th pattern may have interlaced trapezoidal shapes and the upper second pattern may be configured by a single pattern, and the upper second pattern may have the same refractive index as the lower 2-1-th pattern.

The lower 1-1-th pattern, the upper 1-1-th pattern and the lower 2-1-th pattern may have the shape and size and the lower 1-2-th pattern, the upper 1-2-th pattern and the lower 2-2-th pattern may have the same shape and size.

The viewing angle enhancement film may include a base member, a lower first pattern disposed in a center area below the base member and an upper first pattern disposed in a center area above the base member and a lower second pattern disposed in a side area below the base member and an upper second pattern disposed in a side area above the base member.

The lower first pattern may includes a lower 1-1-th pattern and a lower 1-2-th pattern which are alternately disposed, the lower 1-1-th pattern and the lower 1-2-th pattern may have different refractive indexes, and the lower 1-1-th pattern and the lower 1-2-th pattern may have interlaced trapezoidal shapes.

The upper first pattern may include an upper 1-1-th pattern and an upper 1-2-th pattern which are alternately disposed, the upper 1-1-th pattern and the upper 1-2-th pattern may have different refractive indexes, and the upper 1-1-th pattern and the upper 1-2-th pattern may have interlaced trapezoidal shapes.

The lower second pattern may include a lower 2-1-th pattern and a lower 2-2-th pattern which are alternately disposed, the lower 2-1-th pattern and the lower 2-2-th pattern may have different refractive indexes, and the lower 2-1-th pattern and the lower 2-2-th pattern may have interlaced trapezoidal shapes.

The upper second pattern may be configured by a single pattern and the upper second pattern may have the same refractive index as the lower 2-1-th pattern.

The lower 1-1-th pattern, the upper 1-1-th pattern and the lower 2-1-th pattern may have the shape and size and the lower 1-2-th pattern, the upper 1-2-th pattern and the lower 2-2-th pattern may have the same shape and size.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate including a plurality of sub pixels;
a transistor disposed above the substrate;
a planarization film which is disposed above the transistor and has a protrusion portion;
an anode which is disposed on a top surface of the protrusion portion of the planarization film to form a main emission area of the sub pixel;
an organic layer disposed on the anode;
a cathode disposed on the organic layer; and
a viewing angle enhancement film disposed under the substrate, in which two patterns with different refractive indexes are alternately disposed.

2. The display device according to claim 1, wherein the protrusion portion further includes a side portion which extends from the top surface of the protrusion portion to a side surface, and
wherein the cathode includes:
a first area disposed in the main emission area and a second non-emission area; and
a second area which extends from the first area of the cathode to form a reflective emission area corresponding to the side portion of the protrusion portion.

3. The display device according to claim 2, wherein the reflective emission area is formed between the second non-emission area and a first non-emission area along an outline of the main emission area.

4. The display device according to claim 1, wherein the viewing angle enhancement film includes:
a base member; and
a first pattern disposed in a center area above the base member and a second pattern disposed in a side area.

5. The display device according to claim 4, wherein the center area is located in a center of the main emission area and the side area is disposed at an outside of the center area.

6. The display device according to claim 4, wherein the first pattern includes a lower first pattern which is located on a relatively lower layer and an upper first pattern which is located on a relatively upper layer, the second pattern is configured by a single layer, the lower first pattern includes a lower 1-1-th pattern and a lower 1-2-th pattern which are alternately disposed, the lower 1-1-th pattern and the lower 1-2-th pattern have different refractive indexes, and the lower 1-1-th pattern and the lower 1-2-th pattern have interlaced trapezoidal shapes.

7. The display device according to claim 6, wherein the upper first pattern includes an upper 1-1-th pattern and an upper 1-2-th pattern which are alternately disposed, the upper 1-1-th pattern and the upper 1-2-th pattern have different refractive indexes, and the upper 1-1-th pattern and the upper 1-2-th pattern have interlaced trapezoidal shapes.

8. The display device according to claim 7, wherein the upper 1-2-th pattern is disposed on the lower 1-1-th pattern and the upper 1-1-th pattern is disposed on the lower 1-2-th pattern.

9. The display device according to claim 7, wherein the second pattern includes a 2-1-th pattern and a 2-2-th pattern which are alternately disposed, the 2-1-th pattern and the 2-2-th pattern have different refractive indexes, and the 2-1-th pattern and the 2-2-th pattern have interlaced trapezoidal shapes.

10. The display device according to claim 9, wherein the 2-1-th pattern has the same shape as the lower 1-1-th pattern and the upper 1-1-th pattern and is larger than the lower 1-1-th pattern and the upper 1-1-th pattern, and the 2-2-th pattern has the same shape as the lower 1-2-th pattern and the upper 1-2-th pattern and is larger than the lower 1-2-th pattern and the upper 1-2-th pattern.

11. The display device according to claim 9, wherein the lower 1-1-th pattern, the upper 1-1-th pattern and the 2-1-th pattern have the same refractive index, and the lower 1-2-th pattern, the upper 1-2-th pattern and the 2-2-th pattern have the same refractive index.

12. The display device according to claim 4, wherein the first pattern includes a lower first pattern which is located on a relatively lower layer and an upper first pattern which is located on a relatively upper layer, and the second pattern includes a lower second pattern which is located on the relatively lower layer and an upper second pattern which is located on the relatively upper layer.

13. The display device according to claim 12, wherein the lower first pattern includes a lower 1-1-th pattern and a lower 1-2-th pattern which are alternately disposed, the lower 1-1-th pattern and the lower 1-2-th pattern have different refractive indexes,
wherein the lower second pattern includes a lower 2-1-th pattern and a lower 2-2-th pattern which are alternately disposed, the lower 2-1-th pattern and the lower 2-2-th pattern have different refractive indexes, the lower 2-1-th pattern and the lower 2-2-th pattern have interlaced trapezoidal shapes, and
wherein the upper second pattern is configured by a single pattern, and the upper second pattern has the same refractive index as the lower 2-1-th pattern.

14. The display device according to claim 13, wherein the lower 1-1-th pattern, the upper 1-1-th pattern and the lower 2-1-th pattern have the shape and size, and the lower 1-2-th pattern, the upper 1-2-th pattern and the lower 2-2-th pattern have the same shape and size.

15. The display device according to claim 1, wherein the viewing angle enhancement film includes:
a base member;
a lower first pattern disposed in a center area below the base member and an upper first pattern disposed in a center area above the base member; and
a lower second pattern disposed in a side area below the base member and an upper second pattern disposed in a side area above the base member.

16. The display device according to claim 15, wherein the lower first pattern includes a lower 1-1-th pattern and a lower 1-2-th pattern which are alternately disposed, the lower 1-1-th pattern and the lower 1-2-th pattern have different refractive indexes, and the lower 1-1-th pattern and the lower 1-2-th pattern have interlaced trapezoidal shapes.

17. The display device according to claim 12, wherein the upper first pattern includes an upper 1-1-th pattern and an upper 1-2-th pattern which are alternately disposed, the upper 1-1-th pattern and the upper 1-2-th pattern have different refractive indexes, and the upper 1-1-th pattern and the upper 1-2-th pattern have interlaced trapezoidal shapes.

18. The display device according to claim 13, wherein the lower second pattern includes a lower 2-1-th pattern and a lower 2-2-th pattern which are alternately disposed, the lower 2-1-th pattern and the lower 2-2-th pattern have different refractive indexes, and the lower 2-1-th pattern and the lower 2-2-th pattern have interlaced trapezoidal shapes.

19. The display device according to claim 18, wherein the upper second pattern is configured by a single pattern and the upper second pattern has the same refractive index as the lower 2-1-th pattern.

20. The display device according to claim 18, wherein the lower 1-1-th pattern, the upper 1-1-th pattern and the lower 2-1-th pattern have the shape and size, and the lower 1-2-th pattern, the upper 1-2-th pattern and the lower 2-2-th pattern have the same shape and size.
